(19) United States
(12) Patent Application Publication
(10) Pub. No.: US 2025/0126999 A1
(43) Pub. Date: Apr. 17, 2025

(54) DISPLAY DEVICE AND METHOD FOR FABRICATING THE SAME

(71) Applicant: Samsung Display Co., LTD., Yongin-si (KR)

(72) Inventors: Dong Hwan SHIM, Yongin-si (KR); Kwang Woo PARK, Yongin-si (KR); Hye Min PARK, Yongin-si (KR); Jin Yong LEE, Yongin-si (KR); Cheol JANG, Yongin-si (KR); Sang Hyun HAN, Yongin-si (KR)

(21) Appl. No.: 18/915,031

(22) Filed: Oct. 14, 2024

(30) Foreign Application Priority Data
Oct. 17, 2023 (KR) 10-2023-0138663

(51) Int. Cl. H10K 59/131; H10K 59/12; H10K 59/122

(52) U.S. Cl. CPC H10K 59/131; H10K 59/1201; H10K 59/122

(57) ABSTRACT

A display device includes a main display area, and a first sub-display area and a second sub-display area around the main display area and located adjacent to each other, a plurality of pixel electrodes in the main display area and spaced from each other, a plurality of first sub-pixel electrodes in the first sub-display area and spaced from each other, a plurality of first copy pixel electrodes in the first sub-display area and connected to the first sub-pixel electrodes via a first bridge electrode, a first pixel defining layer in the main display area and the first sub-display area, and having a plurality of openings therein that overlaps the plurality of pixel electrodes, the plurality of first sub-pixel electrodes, and the plurality of first copy pixel electrodes, a plurality of second sub-pixel electrodes and second copy pixel electrodes in the second sub-display area and spaced from each other.

### CROSS-REFERENCE TO RELATED APPLICATION

The present application claims priority to and the benefit of Korean Patent Application No. 10-2023-0138663, filed on Oct. 17, 2023, in the Korean Intellectual Property Office, the entire disclosure of which is incorporated by reference herein.

### BACKGROUND

### 1. Field

The disclosure relates to a display device and a method for fabricating the same.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and/or smart televisions. The display device may be a flat panel display device such as a liquid crystal display device, a field emission display device and an organic light emitting display device. Among the flat panel display devices, in the light emitting display device, because each of the pixels of a display panel includes a light emitting element capable of emitting light by itself, an image can be displayed without a backlight unit providing light to the display panel.

The display device may further include pixels that emit predetermined light, scan lines, data lines, and power lines for driving the pixels, a scan driver that outputs scan signals to the scan lines, and a display driver that outputs data voltages to the data lines.

### SUMMARY

Aspects and features of embodiments of the present disclosure provide a display device in which electrodes and a pixel defining layer disposed in different adjacent display areas have different structures.

Aspects and features of embodiments of the present disclosure also provide a display device including pixels in which an electrode and a pixel defining layer have different structures and capable of securing light transmittance due to the arrangement of the pixels, and a method for fabricating the same.

However, aspects and features of embodiments of the present disclosure are not restricted to those set forth herein. The above and other aspects and features of embodiments of the present disclosure will become more apparent to one of ordinary skill in the art to which the present disclosure pertains by referencing the detailed description of the present disclosure given below.

According to one or more embodiments of the present disclosure, a display device includes a main display area, and a first sub-display area and a second sub-display area surrounded by the main display area and located adjacent to each other, a plurality of pixel electrodes in the main display area and spaced from each other, a plurality of first sub-pixel electrodes in the first sub-display area and spaced from each other, a plurality of first copy pixel electrodes in the first sub-display area and connected to the first sub-pixel electrodes via a first bridge electrode, a first pixel defining layer in the main display area and the first sub-display area, and having a plurality of openings therein that overlaps the plurality of pixel electrodes, the plurality of first sub-pixel electrodes, and the plurality of first copy pixel electrodes, respectively, a plurality of second sub-pixel electrodes and second copy pixel electrodes in the second sub-display area and spaced from each other, a plurality of connection patterns in the second sub-display area, and each connected to one of the plurality of second sub-pixel electrodes and one of the second copy pixel electrodes, and a second pixel defining layer on the connection patterns, and having a plurality of openings therein that overlaps the plurality of second sub-pixel electrodes and second copy pixel electrodes, respectively, wherein the second pixel defining layer includes a valley portion around a second sub-pixel electrode of the plurality of second sub-pixel electrodes and a second copy pixel electrode of the second copy pixel electrodes connected to each other through a connection pattern from among the plurality of connection patterns.

The connection pattern may be recessed inward from sidewalls of the valley portion and an opening from among the openings of the second pixel defining layer.

The plurality of connection patterns may be separated from each other with respect to the valley portion of the second pixel defining layer.

The connection pattern may be in contact with a side surface of each of the second sub-pixel electrode and the second copy pixel electrode.

The connection pattern may be in contact with a part of a top surface of each of the second sub-pixel electrode and the second copy pixel electrode.

The display device may further include a common electrode on the main display area, the first sub-display area, and the second sub-display area, wherein the common electrode may be in the valley portion of the second pixel defining layer in the second sub-display area.

The common electrode may be not in contact with the connection pattern.

The first pixel defining layer may include an organic insulating material, and the second pixel defining layer may include an inorganic insulating material.

The display device may further include a first bridge pattern extending from the first sub-display area to the second sub-display area, and connected to one of the plurality of second sub-pixel electrodes.

The display device may further include a second bridge pattern overlapping another one of the plurality of second sub-pixel electrodes, and a third bridge pattern connected to the second bridge pattern and extending from the first sub-display area to the second sub-display area.

The display device may further include a plurality of interlayer insulating layers in the second sub-display area, wherein the first bridge pattern and the second bridge pattern may be on an interlayer insulating layer from among the plurality of interlayer insulating layers that is different from another interlayer insulating layer from among the plurality of interlayer insulating layers on which the third bridge pattern is located.

The display device may further include a plurality of first sub-pixel circuits and a plurality of second sub-pixel circuits in the first sub-display area, wherein the first sub-pixel electrodes may overlap at least one of the plurality of the first sub-pixel circuits, at least some of the first copy pixel electrodes are overlap at least one of the plurality of the second sub-pixel circuits, and the first bridge pattern may be electrically connected to one of the plurality of second sub-pixel circuits.

The display device may further include a first interlayer insulating layer in the main display area, the first sub-display area, and the second sub-display area, and a first insulating layer on the first interlayer insulating layer and in the main display area and the first sub-display area, wherein the first insulating layer may include an organic insulating material, and the first interlayer insulating layer may include an inorganic insulating material.

The first insulating layer may do not overlap the connection pattern, the second sub-pixel electrode, and the second copy pixel electrode.

The first sub-pixel electrode, the first copy pixel electrode, and the first bridge electrode in the first sub-display area may be integrated.

According to one or more embodiments of the present disclosure, a method for fabricating a display device, includes preparing a substrate having a plurality of bridge patterns and an interlayer insulating layer on the bridge patterns, and forming a plurality of sub-pixel electrodes and copy pixel electrodes spaced from each other on the interlayer insulating layer, forming a connection pattern layer on the interlayer insulating layer and covering the sub-pixel electrodes and the copy pixel electrodes, and forming an inorganic insulating layer on the connection pattern layer, forming a photoresist including a plurality of openings surrounding a pair of the sub-pixel electrode and the copy pixel electrode without overlapping the sub-pixel electrodes and the copy pixel electrodes, or overlapping one of the sub-pixel electrodes and the copy pixel electrodes, and on the inorganic insulating layer, forming a pixel defining layer by etching the inorganic insulating layer along the opening of the photoresist, and etching the connection pattern layer along an opening formed in the pixel defining layer to partially expose top surfaces of the sub-pixel electrode and the copy pixel electrode, and forming a light emitting layer on each of the sub-pixel electrode and the copy pixel electrode, and forming a common electrode on the light emitting layer and the pixel defining layer.

The pixel defining layer may include a valley portion formed by etching along an opening from among the openings around the pair of the sub-pixel electrode and the copy pixel electrode, and in the forming of the connection pattern layer, the connection pattern layer may be etched along the valley portion to form a plurality of connection patterns separated from each other with respect to the valley portion.

The connection pattern may be in contact with each of the pair of the sub-pixel electrode and the copy pixel electrode.

In the forming of the connection pattern layer, the connection pattern layer may be etched along the opening of the pixel defining layer, and the connection pattern may partially expose top surfaces of the sub-pixel electrode and the copy pixel electrode.

The connection pattern may be recessed inward from sidewalls of the valley portion and the opening of the pixel defining layer.

A display device according to one or more embodiments may secure sufficient light transmittance because an organic insulating layer is not in a sub-display area where an optical device is located. The display device includes a pixel defining layer containing an inorganic insulating material and connection pattern structures that may be formed by different etching processes, so that the connection structure of different electrodes may be formed without an additional process.

However, effects, aspects, and features of embodiments according to the present disclosure are not limited to those discussed above and various other effects, aspects, and features are incorporated herein.

### BRIEF DESCRIPTION OF THE DRAWINGS

The above and other aspects and features of embodiments of the present disclosure will become more apparent by describing in detail embodiments thereof with reference to the attached drawings, in which:

FIG. 1 is a perspective view of a display device according to one or more embodiments;

FIG. 2 is a plan view illustrating the display device of FIG. 1;

FIG. 3 is a cross-sectional view taken along the line A-A′ of FIG. 2;

FIG. 4 is a plan view illustrating a display panel according to one or more embodiments;

FIG. 5 is a pixel circuit diagram of a sub-pixel according to one or more embodiments;

FIG. 6 is a plan view showing the arrangement of pixels in a main display area and a sub-display area of a display device according to one or more embodiments;

FIG. 7 is a plan view showing the arrangement of pixel electrodes included in the main pixel disposed in the main display area of FIG. 6;

FIG. 8 is a plan view showing the arrangement of pixel electrodes included in the sub-pixels disposed in the sub-display area of FIG. 6;

FIG. 9 is a cross-sectional view showing an example of a main display area of a display device according to one or more embodiments;

FIGS. 10 and 11 are cross-sectional views showing an example of a sub-display area of a display device according to one or more embodiments;

FIG. 12 is a cross-sectional view showing the connection between pixel electrodes and connection patterns disposed in a second sub-display area of a display device according to one or more embodiments;

FIG. 13 is a cross-sectional view specifically showing the connection between the pixel electrode and the connection pattern disposed in the second sub-display area of FIG. 12;

FIGS. 14-28 are diagrams sequentially showing a fabricating process of a display device according to one or more embodiments; and

FIG. 29 is a diagram showing one pixel of a second sub-display area of a display device according to one or more embodiments.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that the present disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Hereinafter, embodiments will be described with reference to the accompanying drawings.

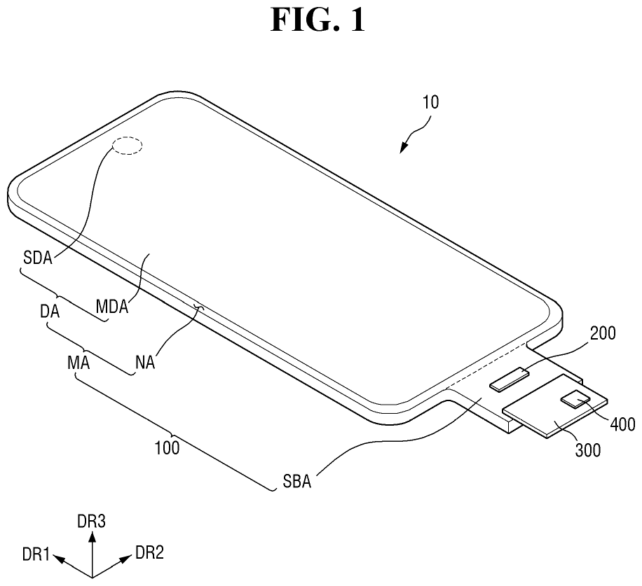

FIG. 1 is a perspective view of a display device according to one or more embodiments.

Referring to FIG. 1, a display device 10 is a device for displaying a moving image and/or a still image. The display device 10 may be used as a display screen of various devices, such as a television, a laptop computer, a monitor, a billboard, and/or an Internet-of-Things (IoT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 10 may be a light emitting display device such as an organic light emitting display including an organic light emitting diode (OLED), a quantum dot light emitting display including a quantum dot light emitting layer, an inorganic light emitting display including an inorganic semiconductor, or a micro light emitting display using a micro or nano light emitting diode (LED). In the following, an embodiment in which the display device 10 is an organic light emitting display device is described, but the type of display device 10 is not limited thereto.

In one or more embodiments, the display device 10 may be formed flat. For example, the display device 10 may be formed substantially flat on a plane defined by a first direction DR1 and a second direction DR2, and may have a suitable thickness (e.g., a predetermined thickness or height) in a third direction DR3. In another embodiment, the display device 10 may include a curved surface in at least a part including an edge region and the like. In addition, the display device 10 may be formed to be flexible so that it can be curved, bent, folded, and/or rolled.

In one or more embodiments, with respect to the image display surface of the display device 10, the first direction DR1 may be a lengthwise direction, a column direction, or a vertical direction, and the second direction DR2 may be a direction intersecting (e.g., crossing) the first direction DR1, for example, a widthwise direction, a row direction, or a horizontal direction. The third direction DR3 may be a thickness direction or a height direction of the display device 10.

The display device 10 may include a display panel 100, a driver 200, and a circuit board 300.

The display panel 100 may include a main region MA including a display area DA in which an image is displayed, and a sub-region SBA located on one side of the main region MA.

The main region MA may include the display area DA and a non-display area NA around (e.g., surrounding) the display area DA along an edge or a periphery of the display area DA. The display area DA may be positioned in the center of the main region MA and occupy most of the area in the main region MA. The non-display area NA may be positioned at an edge of the main region MA and may be in contact with the sub-region SBA.

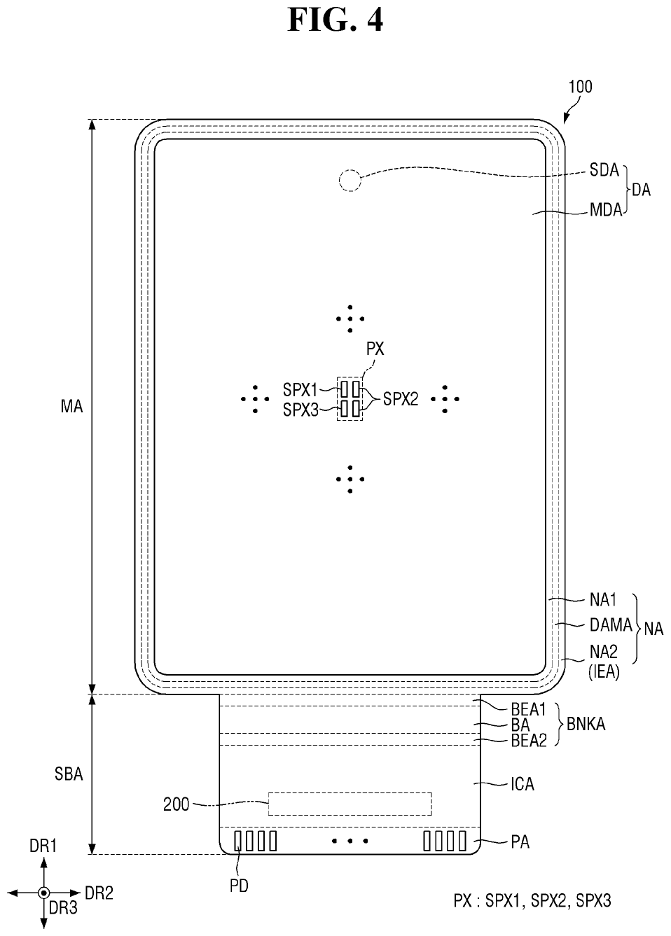

The display area DA may be an area where pixels (e.g., pixels PX in FIG. 4) are arranged and an image is displayed by the pixels PX. In one or more embodiments, the display area DA may be further provided with sensing patterns (e.g., touch electrodes) for detecting a touch input and the like, and the display area DA may include a sensing area for detecting a touch input by the sensing patterns.

In one or more embodiments, the display area DA may include a long side in the first direction DR1 and a short side in the second direction DR2 and may be formed as a plane having an approximately rectangular shape. A corner portion at which the long side and the short side of the display area DA meet may be rounded or right-angled. The shape of the display area DA may be variously changed according to embodiments. For example, the display area DA may be formed in a polygonal shape other than a quadrilateral shape, a circular shape, an elliptical shape, and/or the like.

The display area DA may include a main display area MDA and a sub-display area SDA. The sub-display area SDA may be an area where components for adding various functions to an electronic device are disposed, and the sub-display area SDA may correspond to a component area.

The non-display area NA may be located immediately around the display area DA. The non-display area NA may surround the display area DA. An embedded circuit may be disposed in the non-display area NA. For example, an embedded circuit including a scan driving circuit or the like may be disposed in the non-display area NA positioned on one side (e.g., the left side or the right side) or both sides of the display area DA.

The sub-region SBA may be located on one side of the main region MA. For example, the sub-region SBA may be a region protruding in the first direction DR1 from one side of the main region MA. For example, the sub-region SBA may protrude in the first direction DR1 from the lower end of the main region MA. In one or more embodiments, the sub-region SBA may have a narrower width than the main region MA. For example, with respect to the second direction DR2, the sub-region SBA may have a narrower width than the main region MA.

Wires and pads may be disposed in the sub-region SBA. For example, in the sub-region SBA, the wires and pads connected to the pixels and/or the embedded circuit positioned in the main region MA and to the driver 200 and/or the circuit board 300 positioned in the sub-region SBA may be disposed. In describing embodiments, the term “connect” may include electrical connection and/or physical connection.

In one or more embodiments, the driver 200 (e.g., the display driving circuit) may be mounted in the sub-region SBA. The circuit board 300 may be disposed on a portion of the sub-region SBA.

The driver 200 may include a data driving circuit to drive pixels. In one or more embodiments, the driver 200 may be formed as an integrated circuit chip (IC) and disposed in the sub-region SBA. In one or more embodiments, the driver 200 may be disposed on the circuit board 300 on the sub-region SBA or may be disposed on another circuit board connected to the display panel 100 through the circuit board 300.

The circuit board 300 may be disposed on a part of the sub-region SBA. For example, the circuit board 300 may be bonded on the pads positioned on a portion (e.g., a lower edge) of the sub-region SBA, and may supply or transmit power voltages and driving signals for driving the display panel 100 to the display panel 100. For example, the circuit board 300 may supply input image data (e.g., digital image data), driving signals including timing signals, and driving voltages to the display panel 100. The circuit board 300 may be a flexible film such as a flexible printed circuit board (FPCB), a printed circuit board (PCB), or a chip on film (COF), but is not limited thereto.

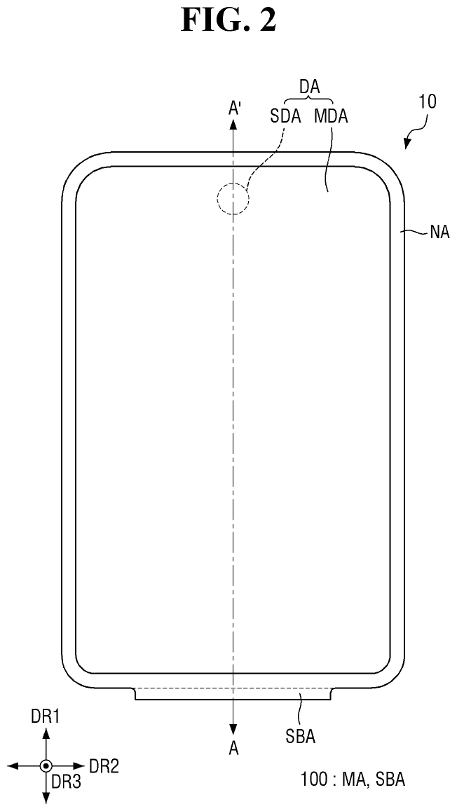

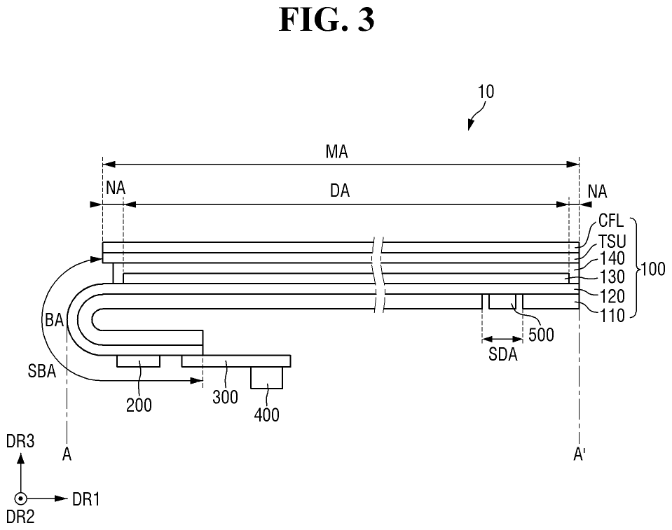

FIG. 2 is a plan view illustrating the display device of FIG. 1. FIG. 3 is a cross-sectional view taken along the line A-A′ of FIG. 2.

FIG. 1 illustrates the display device 10 unfolded without bending, and FIGS. 2 and 3 illustrate the display device 10 bent in the sub-region SBA. FIG. 1 shows the sub-region SBA unfolded alongside the main region MA, and FIGS. 2 and 3 show a part of the sub-region SBA in a bent state.

Referring to FIGS. 2 and 3, the display panel 100 may include a substrate 110 including the main region MA and the sub-region SBA, and a circuit layer 120, a light emitting element layer 130, an encapsulation layer 140, a touch sensing layer TSU, and a color filter layer CFL sequentially disposed on the substrate 110. The circuit layer 120 may also be positioned in the main region MA and the sub-region SBA on the substrate 110. The light emitting element layer 130 and the encapsulation layer 140 may be positioned on a part of the substrate 110 and the circuit layer 120. For example, the light emitting element layer 130 and the encapsulation layer 140 may be positioned in the main region MA.

In one or more embodiments, the display device 10 may further include an additional element disposed on the display panel 100. For example, the display device 10 may further include at least one of a polarization layer or a protective layer (e.g., a window) disposed on the encapsulation layer 140. Each of the polarization layer and/or the protective layer may be fabricated integrally with the display panel 100 or may be fabricated separately from the display panel 100 and attached to the display panel 100 through an adhesive layer or the like.

The substrate 110 may include an insulating material such as a polymer resin. For example, the substrate 110 may be made of polyimide or another insulating material. The substrate 110 may be a flexible substrate that can be transformed, such as bending, folding, and/or rolling. Alternatively, the substrate 110 may include an insulating material such as glass.

The circuit layer 120 may include pixel circuits and wires. For example, the circuit layer 120 may include circuit elements (e.g., pixel transistors and/or capacitors) constituting a pixel circuit for each pixel, and wires connected to the pixels. In one or more embodiments, the circuit layer 120 may further include circuit elements constituting an embedded circuit, such as a scan driving circuit, and wires connected to the embedded circuit.

The light emitting element layer 130 may include light emitting elements disposed in emission areas of the pixels. For example, each of the pixels may include at least one light emitting element and a pixel circuit connected to the light emitting element. Each of the pixels may be located in a pixel region, including the emission area where the light emitting element is disposed and a pixel circuit area where the pixel circuit is disposed. The emission area and the pixel circuit area of each pixel may overlap each other, but the present disclosure is not limited thereto.

In describing the embodiments, the circuit layer 120 and the light emitting element layer 130 are separately described, but the present disclosure is not limited thereto. For example, the circuit layer 120 and the light emitting element layer 130 may be integrated.

The encapsulation layer 140 may cover the light emitting element layer 130 and may extend to the non-display area NA to be in contact with the circuit layer 120. In one or more embodiments, the encapsulation layer 140 may have a multilayer structure including at least two inorganic encapsulation layers overlapping each other and at least one organic encapsulation layer interposed between the inorganic encapsulation layers.

The touch sensing layer TSU may be disposed on the encapsulation layer 140. The touch sensing layer TSU may include a plurality of touch electrodes for sensing a user's touch in a capacitive manner, and touch lines connecting the plurality of touch electrodes to the touch driver 400. For example, the touch sensing layer TSU may sense the user's touch by using a mutual capacitance method or a self-capacitance method.

In one or more embodiments, the touch sensing layer TSU may be disposed on a separate substrate disposed on the display panel 100. In this case, the substrate supporting the touch sensing layer TSU may be a base member that encapsulates the display panel 100.

The plurality of touch electrodes of the touch sensing layer TSU may be disposed in a touch sensor area overlapping the display area DA. The touch lines of the touch sensing layer TSU may be disposed in a touch peripheral area that overlaps the non-display area NA.

In one or more embodiments, the display device 10 may further include an optical device 500. The optical device 500 may be disposed in the sub-display area SDA. The optical device 500 may emit or receive light in infrared, ultraviolet, and/or visible light bands. For example, the optical device 500 may be an optical sensor that detects light incident on the display device 10 such as a proximity sensor, an illuminance sensor, and a camera sensor, and/or an image sensor.

The color filter layer CFL may be disposed on the touch sensing layer TSU. The color filter layer CFL may include a plurality of color filters respectively corresponding to the plurality of emission areas. Each of the color filters may selectively transmit light of a specific wavelength and may block or absorb light of a different wavelength. The color filter layer CFL may absorb a part of light coming from the outside of the display device 10 to reduce reflected light due to external light. Accordingly, the color filter layer CFL may prevent or reduce color distortion caused by reflection of the external light.

Because the color filter layer CFL is directly disposed on the touch sensing layer TSU, the display device 10 may not require a separate substrate for the color filter layer CFL. Accordingly, the thickness of the display panel 100 may be relatively small.

In one or more embodiments, the display panel 100 may be bent in a bending area BA. The bending area BA may be a part of the sub-region SBA and may be spaced from the main region MA.

The substrate 110 and the circuit layer 120 may be bent in the bending area BA corresponding to a partial section of the sub-region SBA. Accordingly, the bezel area recognized by a user as the non-display area NA may be reduced or minimized.

FIG. 4 is a plan view illustrating a display panel according to one or more embodiments. FIG. 4 shows the display panel 100 in an unbent and unfolded state.

Referring to FIG. 4, the display panel 100 may include the main region MA and the sub-region SBA. The main region MA may include the display area DA and the non-display area NA, and the sub-region SBA may include a bank area BNKA, a driving circuit mounting area ICA, and a pad area PA.

The display area DA may be an area where a plurality of pixels PX are disposed. The pixels PX and wires (or some of the wires) connected to the pixels PX may be disposed in the display area DA.

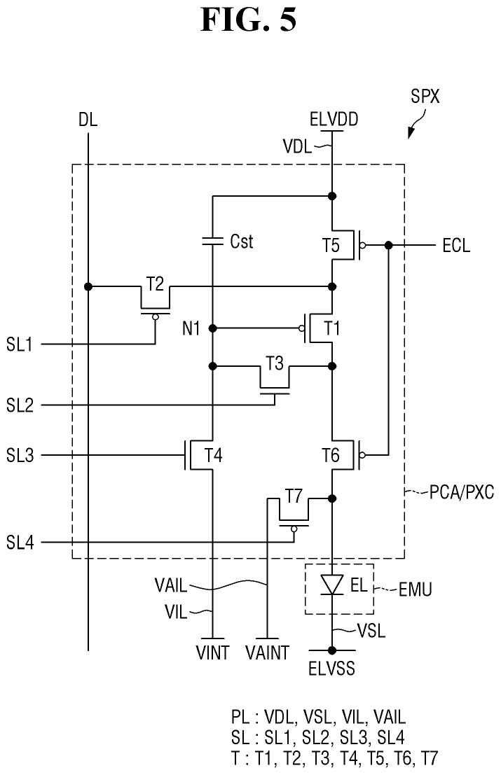

The pixels PX may be provided in the circuit layer 120 and the light emitting element layer 130 of the display panel 100. As an example, each pixel PX may include a pixel circuit (e.g., a pixel circuit PCA of FIG. 5) including circuit elements disposed on the circuit layer 120 and a light emitting element (e.g., a light emitting element EL of FIG. 5) disposed on the light emitting element layer 130.

The pixels PX may include at least two color sub-pixels SPX that emit light of different colors. For example, the pixels PX may include first color sub-pixels SPX1 emitting light of a first color (e.g., red light), second color sub-pixels SPX2 emitting light of a second color (e.g., green light), and third color sub-pixels SPX3 emitting light of a third color (e.g., blue light).

At least one first color sub-pixel SPX1, at least one second color sub-pixel SPX2, and at least one third color sub-pixel SPX3 adjacent to each other may constitute one unit pixel PX. For example, one first color sub-pixel SPX1, two second color sub-pixels SPX2, and one third color sub-pixel SPX3 adjacent to each other may constitute one unit pixel PX. Each unit pixel PX may emit light of various colors, including white light, by color mixing of light emitted from the sub-pixels SPX1, SPX2, and SPX3 constituting the unit pixel PX. In one or more embodiments, the first color sub-pixels SPX1 and the third color sub-pixels SPX3 may be arranged alternately along the first direction DR1 and/or the second direction DR2, and the second color sub-pixels SPX2 may be arranged continuously and/or sequentially along the first direction DR1. The type, shape, and/or arrangement structure of the sub-pixels SPX1, SPX2, and SPX3 may be changed depending on the embodiments. In addition, the type, number, ratio, and/or arrangement structure of the sub-pixels SPX1, SPX2, and SPX3 constituting each unit pixel PX may also be changed depending on the embodiments.

The encapsulation layer 140 may be disposed on the pixels PX. For example, the encapsulation layer 140 may be provided in at least the display area DA to cover the pixels PX, and a part of the encapsulation layer 140 may extend into the non-display area NA.

Wires may be provided in the circuit layer 120 and may be positioned in the display area DA and the non-display area NA. In addition, wires may be positioned also in the sub-region SBA. For example, the wires may extend from the sub-region SBA through the non-display area NA to the display area DA.

The non-display area NA may be located around the display area DA. For example, the non-display area NA may be an edge area of the main region MA positioned outside the display area DA.

The non-display area NA may include a dam area DAMA spaced from the display area DA, a first non-display area NA1 between the display area DA and the dam area DAMA, and a second non-display area NA2 outside the dam area DAMA. The dam area DAMA may be an area in which a dam around (e.g., surrounding) the display area DA is disposed. The second non-display area NA2 may include an inorganic encapsulation area IEA (also referred to as a “bonding area”) in which the inorganic encapsulation layers of the encapsulation layer 140 are bonded to each other.

The sub-region SBA may include the bank area BNKA, the driving circuit mounting area ICA, and the pad area PA sequentially disposed on one side of the main region MA. Wires (or parts of wires), banks, and the pads PD may be disposed in the sub-region SBA. At least some of the wires may extend into the main region MA and may be connected to the pixels PX.

The bank area BNKA may be an area in which a bank including at least one organic layer is disposed. In one or more embodiments, the bank area BNKA may include the bending area BA. For example, the bank area BNKA may include the bending area BA spaced from the main region MA, and a first edge area BEA1 and a second edge area BEA2 positioned on both sides of the bending area BA in the first direction DR1. The bank may be provided in the bending area BA and the peripheral areas thereof (e.g., the first edge area BEA1 and the second edge area BEA2 of the bank area BNKA) to cover wires passing through the bending area BA. The display panel 100 may be bent in the bending area BA such that a part of the sub-region SBA may be positioned behind the main region MA.

The driving circuit mounting area ICA may be an area in which the driver 200 is disposed. Pads for connecting at least some of the wires to the driver 200 may be disposed in the driving circuit mounting area ICA. For example, in the driving circuit mounting area ICA, input pads for connecting the driver 200 to the specific pads (e.g., data input pads) of the pad area PA and output pads for connecting the driver 200 to the pixels PX may be disposed.

In one or more embodiments, the driver 200 may not be disposed on the display panel 100. In this case, the display panel 100 may not include the driving circuit mounting area ICA, and only wires may be disposed in an area between the bank area BNKA and the pad area PA.

The pad area PA may be an area where the pads PD for connecting the display panel 100 and/or the driver 200 to the circuit board 300 and the like are disposed. The circuit board 300 may be disposed or bonded on the pad area PA.

A plurality of pads PD including power pads and signal pads connected to the pixels PX, the driver 200, and/or the embedded circuit may be disposed in the pad area PA. Power voltages for driving the pixels PX, the driver 200, and/or the embedded circuit or the like may be supplied to the power pads. Driving signals and/or image data for driving the pixels PX, the driver 200, and/or the embedded circuit or the like may be supplied to the signal pads (e.g., pads PD). The type, location, arrangement order, and/or number of the pads PD may be variously changed according to embodiments.

FIG. 5 is a pixel circuit diagram of a sub-pixel according to one or more embodiments.

Referring to FIG. 5, each pixel circuit PCA of the display device 10 according to one or more embodiments may include first to seventh transistors T1 to T7. The scan lines SL connected to the sub-pixel SPX may include a first scan line SL1, a second scan line SL2, a third scan line SL3, and a fourth scan line SL4, and the power lines PL connected to the sub-pixel SPX may include a first pixel power line VDL, a second pixel power line VSL, a first initialization power line VIL, and a second initialization power line VAIL. In addition, the pixel circuit PCA may be further connected to an emission control line ECL.

A sub-pixel SPX may include a light emitting unit EMU including at least one light emitting element EL and the pixel circuit PCA (also referred to as a “pixel driver”) connected to the light emitting unit EMU.

The light emitting element EL may be connected between the pixel circuit PCA and the second pixel power line VSL to which the second pixel power voltage ELVSS is applied. In one or more embodiments, the second pixel power voltage ELVSS may be a low potential pixel driving voltage. The light emitting element EL, which is a light source of the sub-pixel SPX, may emit light in response to the driving current supplied from the pixel circuit PCA.

The light emitting element EL may be an organic light emitting diode (OLED), but is not limited thereto. For example, the light emitting element EL may be an inorganic light emitting element, a quantum dot light emitting element, or another type of light emitting element.

The pixel circuit PCA may control the light emitting timing and luminance of the light emitting element EL by controlling the driving current supplied to the light emitting element EL. The pixel circuit PCA may include at least one pixel transistor T and a capacitor Cst. In one or more embodiments, the pixel circuit PCA may include pixel transistors T including the first to seventh transistors T1 to T7.

The first transistor T1 may include a gate electrode connected to the first node N1, a first electrode electrically connected to the first pixel power line VDL through the fifth transistor T5, and a second electrode electrically connected to the light emitting unit EMU through the sixth transistor T6. One of the first electrode and the second electrode may be a source electrode and the other one may be a drain electrode. The first transistor T1 may control a source-drain current (hereinafter referred to as a “driving current”) flowing between the first electrode and the second electrode of the first transistor T1 according to the voltage (e.g., the voltage of the first node N1 corresponding to the voltage of the data signal) applied to the gate electrode of the first transistor T1. For example, the first transistor T1 may be a driving transistor of the sub-pixel SPX.

The second transistor T2 may include a gate electrode connected to the first scan line SL1, a first electrode connected to the data line DL, and a second electrode connected to the first electrode of the first transistor T1. The second transistor T2 may be turned on by the first scan signal supplied to the first scan line SL1 to electrically connect the first electrode of the first transistor T1 to the data line DL. When the second transistor T2 is turned on, the voltage of the data signal supplied to the data line DL may be applied to the first electrode of the first transistor T1.

The third transistor T3 may include a gate electrode connected to the second scan line SL2, a first electrode connected to the second electrode of the first transistor T1, and a second electrode connected to a gate electrode (or the first node N1) of the first transistor T1. The third transistor T3 may be turned on by the second scan signal supplied to the second scan line SL2 to electrically connect the gate electrode of the first transistor T1 to the second electrode of the first transistor T1. When the third transistor T3 is turned on, the first transistor T1 may be driven as a diode (e.g., the first transistor T1 may be diode-connected).

The fourth transistor T4 may include a gate electrode connected to the third scan line SL3, a first electrode connected to the gate electrode of the first transistor T1 (or the first node N1), and a second electrode connected to the first initialization power line VIL. The fourth transistor T4 may be turned on by the third scan signal supplied to the third scan line SL3 to electrically connect the gate electrode of the first transistor T1 to the first initialization power line VIL. When the fourth transistor T4 is turned on, a first initialization voltage VINT (e.g., the gate initialization voltage) of the first initialization power line VIL may be applied to the gate electrode of the first transistor T1.

The fifth transistor T5 may include a gate electrode connected to the emission control line ECL, a first electrode connected to the first pixel power line VDL, and a second electrode connected to the first electrode of the first transistor T1. The fifth transistor T5 may be turned on by the emission control signal supplied to the emission control line ECL, and thus may electrically connect the first electrode of the first transistor T1 to the first pixel power line VDL to which a first pixel power voltage ELVDD is applied. When the fifth transistor T5 is turned on, the first pixel power voltage ELVDD may be applied to the first electrode of the first transistor T1. In one or more embodiments, the first pixel power voltage ELVDD may be a high potential pixel driving voltage.

The sixth transistor T6 may include the gate electrode connected to the emission control line ECL, the first electrode connected to the second electrode of the first transistor T1, and the second electrode connected to the light emitting element EL. The sixth transistor T6 may be turned on by the emission control signal supplied to the emission control line ECL to electrically connect the first transistor T1 to the light emitting element EL. When all of the fifth transistor T5 and the sixth transistor T6 are turned on, the driving current having a magnitude corresponding to the voltage of the gate electrode of the first transistor T1 may flow through the light emitting element EL.

The seventh transistor T7 may include a gate electrode connected to the fourth scan line SL4, a first electrode connected to the anode electrode of the light emitting element EL, and a second electrode connected to the second initialization power line VAIL. The seventh transistor T7 may be turned on by the fourth scan signal supplied to the fourth scan line SL4 to electrically connect the anode electrode of the light emitting element EL to the second initialization power line VAIL. The fourth scan signal may be the same signal as or a different signal from the first scan signal. When the seventh transistor T7 is turned on, the second initialization voltage VAINT (e.g., an anode initialization voltage) of the second initialization power line VAIL may be applied to the anode electrode of the light emitting element EL.

The capacitor Cst may be connected between the gate electrode of the first transistor T1 (e.g., connected between the first node N1) and the first pixel power line VDL. The capacitor Cst may be charged with a voltage corresponding to the voltage of the data signal applied to the gate electrode of the first transistor T1 (e.g., to the first node N1).

The active layer (e.g., a semiconductor pattern including a channel region) of each of the pixel transistors T (e.g., the first to seventh transistors T1 to T7) may include one semiconductor material of polysilicon, amorphous silicon, and an oxide semiconductor. In one or more embodiments, some of the pixel transistors T and some others thereof may be formed of transistors of different conductivity types. In addition, some of the pixel transistors T and some others thereof may include different types of semiconductor materials.

For example, the first, second, fifth, sixth, and seventh transistors T1, T2, T5, T6, and T7 may be formed of P-type transistors (e.g., P-type MOSFETs) including the respective active layers formed of polysilicon, and the third and fourth transistors T3 and T4 may be formed of N-type transistors (e.g., N-type MOSFETs) including the respective active layers formed of an oxide semiconductor. In one or more embodiments, transistors including the respective active layers formed of polysilicon and transistors including the respective active layers formed of an oxide semiconductor may be disposed on different layers in the circuit layer 120.

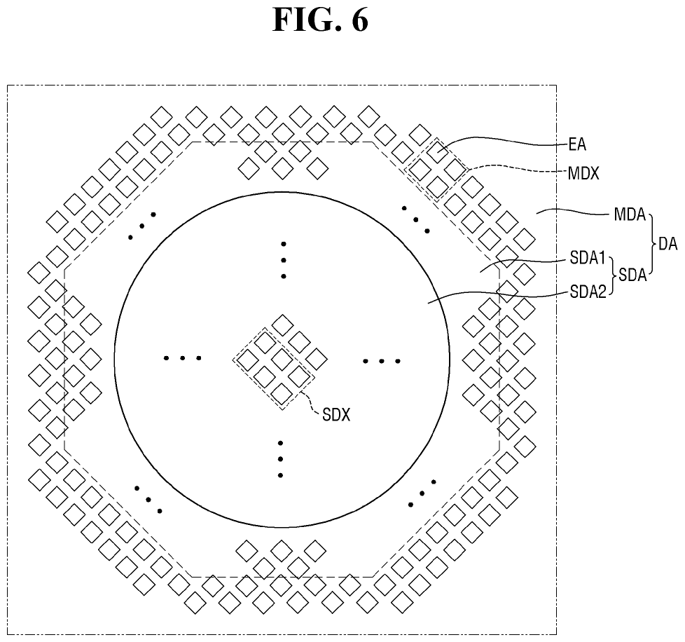

FIG. 6 is a plan view showing the arrangement of pixels in a main display area and a sub-display area of a display device according to one or more embodiments. FIG. 6 shows the arrangement of pixels MDX and SDX in the sub-display area SDA and the main display area MDA disposed around the sub-display area SDA in the display area DA of the display device 10.

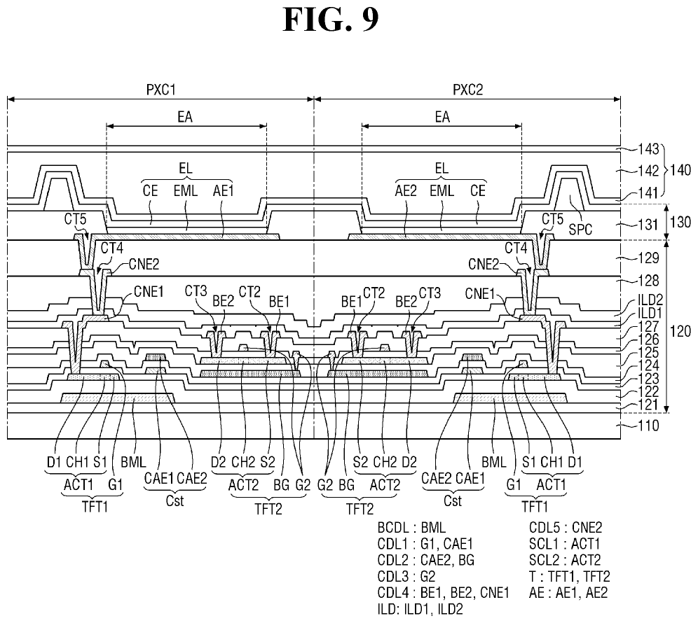

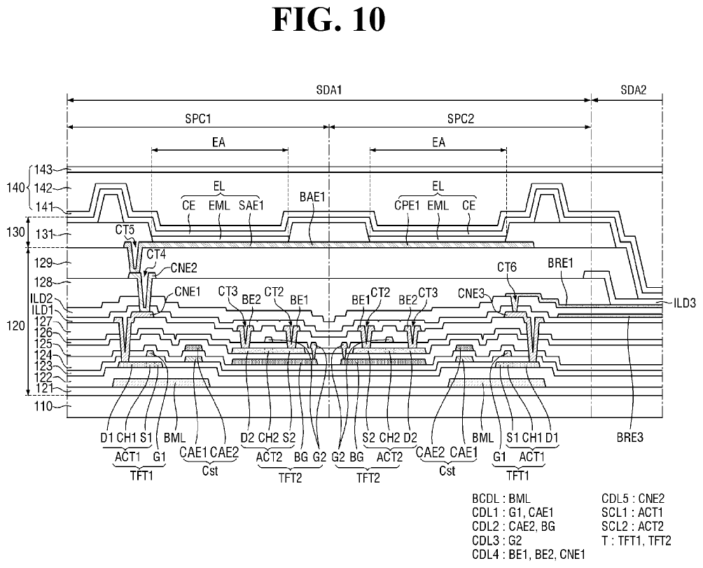

Referring to FIG. 6, in the display device 10 according to one or more embodiments, the display area DA may include the main display area MDA and the sub-display area SDA. As described above, the sub-display area SDA may be an area where components are disposed under a substrate 110 of the display device 10. A plurality of main display pixels MDX may be arranged in the main display area MDA, and a plurality of sub-display pixels SDX may be arranged in the sub-display area SDA. The main display pixels MDX and the sub-display pixels SDX may each include one or more emission areas EA, and a light emitting element EL (see FIGS. 9 and 10) may be disposed in each emission area EA to emit light.

A plurality of light emitting elements EL that emit light, and pixel circuits PCA that are electrically connected to the light emitting element EL and applies a signal for light emission of the light emitting element EL may be disposed in the main display area MDA. The main display area MDA may be an area where the light emitting elements EL and the pixel circuits PCA are arranged in specific arrangement. Each of the light emitting elements EL may form the emission area EA, and a plurality of emission areas EA may constitute one main display pixel MDX. For example, in the main display area MDA, four emission areas EA may constitute one main display pixel MDX, and each of the emission areas EA may correspond to the pixel circuit PCA of the sub-pixel SPX. As illustrated in FIG. 4, one main display pixel MDX may include four sub-pixels SPX1, SPX2, and SPX3, and may include four emission areas EA corresponding to the sub-pixels SPX1, SPX2, and SPX3. The four emission areas EA may constitute one main display pixel MDX to express a white gray level.

The light emitting elements EL that emit light may also be disposed in the sub-display area SDA to form the emission area EA, and the plurality of emission areas EA may constitute one sub-display pixel SDX. However, the sub-display area SDA may be an area that overlaps a component, for example, the optical device 500, disposed on the back surface of the substrate 110 of the display panel 100, and may have a structure in which transmittance of light is considered, unlike the main display area MDA. Accordingly, the sub-display area SDA of the display area DA may include a first sub-display area SDA1 where the emission area EA and the pixel circuits PCA are disposed, and a second sub-display area SDA2 where the emission area EA is formed and the pixel circuit PCA is not disposed.

The first sub-display area SDA1 may be disposed around the second sub-display area SDA2. In one or more embodiments, the second sub-display area SDA2 of the sub-display area SDA may be disposed at the center, and the first sub-display area SDA1 thereof may surround the second sub-display area SDA2. However, the present disclosure is not limited thereto, and the first sub-display area SDA1 may be disposed only on at least one side of the second sub-display area SDA2.

The pixel circuits PCA (e.g., PXC1, PXC2, PXC3) for light emission of the light emitting elements EL of the plurality of emission areas EA disposed in the first sub-display area SDA1 and the second sub-display area SDA2 may be disposed in the first sub-display area SDA1 of the sub-display area SDA. On the other hand, the pixel circuits PCA may not be disposed in the second sub-display area SDA2.

The pixel circuits PCA electrically connected to the light emitting elements EL disposed in the sub-display area SDA may be disposed in the first sub-display area SDA1. Some of the pixel circuits PCA disposed in the first sub-display area SDA1 may be electrically connected to the light emitting element EL disposed in the first sub-display area SDA1, and some others of the pixel circuits PCA may be electrically connected to the light emitting element EL disposed in the second sub-display area SDA2. The second sub-display area SDA2, which is an area that overlaps the optical device 500 of the display panel 100, may have high transmittance because the pixel circuits PCA are not disposed therein. The second sub-display area SDA2 where the emission areas EA are disposed may emit light and have high transmittance so that the optical device 500 disposed on the back surface of the display panel 100 may receive light.

Unlike the main display area MDA, in the sub-display area SDA, one light emitting element EL and one pixel circuit PCA may not correspond to each other. For example, one pixel circuit PCA disposed in the main display area MDA may be electrically connected to one light emitting element EL. In the main display area MDA, the pixel circuit PCA may correspond to one light emitting element EL, or a light emitting element formed at one opening of a pixel defining layer 131 (see FIG. 9) to be described later. On the other hand, in the sub-display area SDA, the pixel circuits PCA disposed in the first sub-display area SDA1 may be electrically connected to the light emitting elements EL disposed in the first sub-display area SDA1 and the second sub-display area SDA2. Accordingly, the pixel circuit PCA disposed in the first sub-display area SDA1 may correspond to the plurality of light emitting elements EL, or light emitting elements formed at a plurality of openings of the pixel defining layer 131 (see FIG. 9) to be described later.

The sub-display pixel SDX formed by the plurality of emission areas EA of the sub-display area SDA may have arrangement different from that of the main display pixel MDX. For example, the main display pixel MDX may include four emission areas EA, whereas the sub-display pixel SDX may include six emission areas EA. Each of the four emission areas EA of the main display pixel MDX may correspond to the pixel circuit PCA, and the main display pixel MDX may include four pixel circuits PCA. On the other hand, in the sub-display pixel SDX, two emission areas EA may form a pair to correspond to one pixel circuit PCA. That is, the sub-display pixel SDX may include six emission areas EA where light is emitted by three pixel circuits PCA. Accordingly, the luminance and resolution of the sub-display area SDA may be different from those of the main display area MDA.

Hereinafter, the arrangement and structure of the pixels MDX and SDX in the main display area MDA and the sub-display area SDA of the display device 10 will be described in detail with further reference to other drawings.

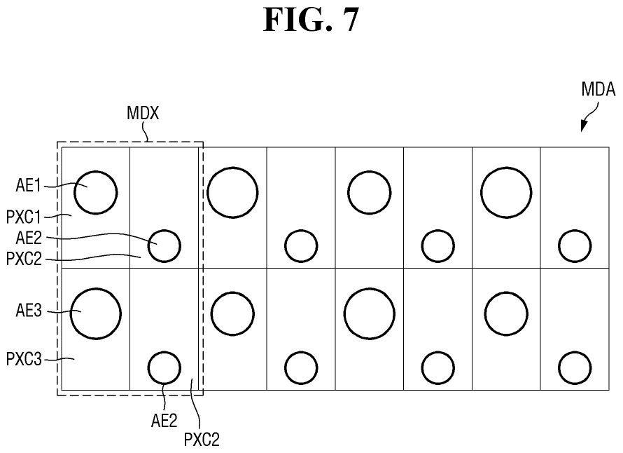

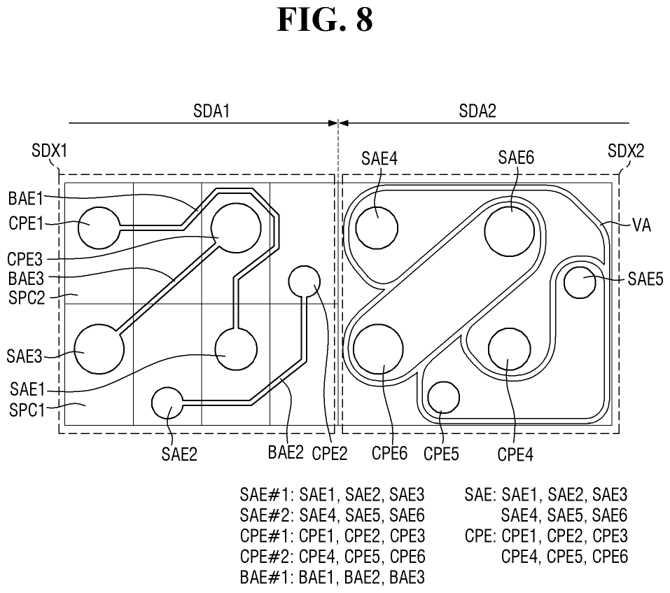

FIG. 7 is a plan view showing the arrangement of pixel electrodes included in the main pixel disposed in the main display area of FIG. 6. FIG. 8 is a plan view showing the arrangement of pixel electrodes included in the sub-pixels disposed in the sub-display area of FIG. 6.

FIG. 7 shows the arrangement of pixel electrodes AE1, AE2, and AE3 and pixel circuits PXC1, PXC2, and PXC3 of four main display pixels MDX. FIG. 8 illustrates the arrangement of one sub-display pixel SDX1 of the first sub-display area SDA1, sub-pixel electrodes SAE1, SAE2, and SAE3 of the sub-display pixel SDX1, and sub-pixel electrodes SAE4, SAE5, and SAE6 of one sub-display pixel SDX2 of the second sub-display area SDA2, and sub-pixel circuits SPC1 and SPC2.

Referring to FIG. 7, the display device 10 may include the plurality of pixel electrodes AE1, AE2, and AE3 disposed in the main display area MDA. The pixel electrodes AE1, AE2, and AE3 may be anode electrodes of the light emitting elements EL that emit lights of different colors. For example, the first pixel electrode AE1, which is the anode electrode of the light emitting element that emits light of the first color, may be disposed in a first emission area. The second pixel electrode AE2, which is the anode electrode of the light emitting element that emits light of the second color, may be disposed in a second emission area, and the third pixel electrode AE3, which is the anode electrode of the light emitting element that emits light of the third color, may be disposed in a third emission area. In one or more embodiments, the first emission area may emit first light of a red color, the second emission area may emit second light of a green color, and the third emission area may emit third light of a blue color. However, the present disclosure is not limited thereto. The plurality of emission areas may be respectively defined by the openings formed at a first pixel defining layer 131 of the light emitting element layer 130 to be described later.

The plurality of pixel electrodes AE1, AE2, and AE3 may be arranged in a PENTILE® type structure, e.g., a diamond PENTILE® type structure. PENTILE® is a registered trademark of Samsung Display Co., Ltd., Republic of Korea. For example, the first pixel electrode AE1 and the third pixel electrode AE3 may be disposed to be spaced from each other in the vertical direction and the horizontal direction, and they may be disposed alternately. The second pixel electrode AE2 may be spaced from another adjacent second pixel electrode AE2 in the vertical direction and the horizontal direction, and may be spaced from the adjacent first pixel electrode AE1 and the adjacent third pixel electrode AE3 in a diagonal direction.

Each of the first to third pixel electrodes AE1, AE2, and AE3 is a pixel electrode belonging to one sub-pixel SPX, and the plurality of pixel electrodes AE1, AE2, and AE3 may be included in one main display pixel MDX. For example, the main display pixel MDX may include one first sub-pixel SPX1, two second sub-pixels SPX2, and one third sub-pixel SPX3, and the main display pixel MDX may include one first pixel electrode AE1, two second pixel electrodes AE2, and one third pixel electrode AE3.

Each of the plurality of pixel circuits PXC1, PXC2, and PXC3 disposed in the main display area MDA may correspond to one of the pixel electrodes AE1, AE2, and AE3. For example, the first pixel circuit PXC1 may correspond to one first pixel electrode AE1 and may be electrically connected thereto. The second pixel circuit PXC2 may correspond to one second pixel electrode AE2 and may be electrically connected thereto, and the third pixel circuit PXC3 may correspond to one third pixel electrode AE3 and be electrically connected thereto. The main display pixel MDX including the four pixel electrodes AE1, AE2, and AE3 may include the four pixel circuits PXC1, PXC2, and PXC3.

Referring to FIG. 8, the display device 10 may include a plurality of sub-pixel electrodes SAE, copy pixel electrodes CPE, and bridge electrodes BAE that are disposed in the sub-display area SDA. One sub-pixel electrode SAE and one copy pixel electrode CPE may each be the anode electrode of the light emitting element EL. That is, similarly to the main display area MDA, the light emitting elements EL may also be disposed in the sub-display areas SDA1 and SDA2 to emit light.

In the display device 10, the configuration of the sub-display pixel SDX of the sub-display area SDA may be different from that of the main display pixel MDX of the main display area MDA. In the first sub-display pixel SDX1, one sub-pixel electrode SAE and one copy pixel electrode CPE may be electrically connected to each other through the bridge electrode BAE. The sub-pixel electrode SAE and the copy pixel electrode CPE connected through the bridge electrode BAE may be the anode electrodes of the light emitting elements EL that emit light of the same color.

For example, the first sub-pixel electrode SAE1 and a first copy pixel electrode CPE1 disposed in the first sub-display area SDA1 may be electrically connected to each other through a first bridge electrode BAE1, and they may constitute a light emitting element that emits light of the first color. The emission areas where the first sub-pixel electrode SAE1 and the first copy pixel electrode CPE1 are disposed may emit light of the same color.

Similarly, the second sub-pixel electrode SAE2 and a second copy pixel electrode CPE2 disposed in the first sub-display area SDA1 may be electrically connected to each other through a second bridge electrode BAE2, and the third sub-pixel electrode SAE3 and a third copy pixel electrode CPE3 disposed in the first sub-display area SDA1 may be electrically connected to each other through a third bridge electrode BAE3. The second sub-pixel electrode SAE2 and the second copy pixel electrode CPE2 may constitute a light emitting element that emits light of the second color, and the third sub-pixel electrode SAE3 and the third copy pixel electrode CPE3 may constitute a light emitting element that emits light of the third color. The emission areas where the second sub-pixel electrode SAE2 and the second copy pixel electrode CPE2 are disposed may emit light of the same color, and the emission areas where the third sub-pixel electrode SAE3 and the third copy pixel electrode CPE3 are disposed may emit light of the same color.

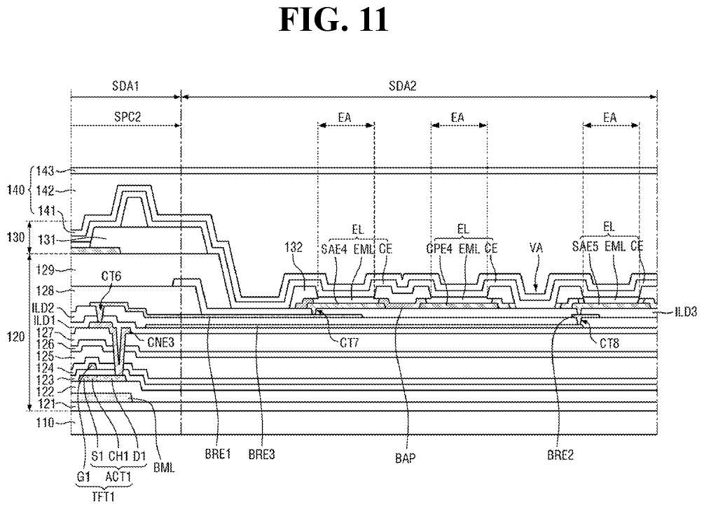

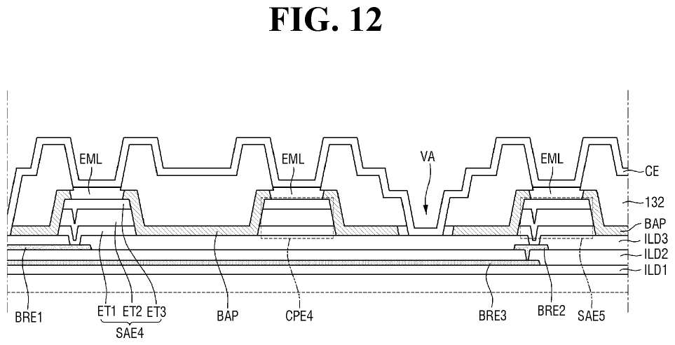

In accordance with one or more embodiments, the sub-pixel electrodes SAE4, SAE5, and SAE6 and copy pixel electrodes CPE4, CPE5, and CPE6 disposed in the second sub-display area SDA2 may be electrically connected to each other through a connection pattern BAP (see FIGS. 11 and 12) disposed across the entire second sub-display area SDA2. The fourth to sixth sub-pixel electrodes SAE4, SAE5, and SAE6 and the fourth to sixth copy pixel electrodes CPE4, CPE5, and CPE6 may also be arranged in the second sub-display area SDA2 in the same arrangement as that in the first sub-display area SDA1. However, a pair of the sub-pixel electrode SAE and the copy pixel electrode CPE may be connected through connection patterns disposed therearound, and the connection patterns may be spaced from each other in a valley portion VA of a second pixel defining layer 132 disposed in the second sub-display area SDA2.

The fourth sub-pixel electrode SAE4 and the fourth copy pixel electrode CPE4 may constitute a light emitting element that emits light of the first color, the fifth sub-pixel electrode SAE5 and the fifth copy pixel electrode CPE5 may constitute a light emitting element that emits light of the second color, and the sixth sub-pixel electrode SAE6 and the sixth copy pixel electrode CPE6 may constitute a light emitting element that emits light of the third color.

The plurality of sub-pixel electrodes SAE and the plurality of copy pixel electrodes CPE may be arranged in a PENTILE® type structure, e.g., a diamond PENTILE® type structure, similarly to the pixel electrode AE of the main display area MDA. For example, the first sub-pixel electrode SAE1 and the third sub-pixel electrode SAE3 may be spaced from each other in the horizontal direction, and the third copy pixel electrode CPE3 and the first copy pixel electrode CPE1 may be disposed to be spaced therefrom in the vertical direction. The fourth sub-pixel electrode SAE4 and the sixth sub-pixel electrode SAE6 may be spaced from each other in the horizontal direction, and the sixth copy pixel electrode CPE6 and the fourth copy pixel electrodes CPE4 may be disposed to be spaced therefrom in the vertical direction. The second sub-pixel electrode SAE2 and the second copy pixel electrode CPE2 may be spaced from each other in the diagonal direction with the first sub-pixel electrode SAE1 interposed therebetween. The fifth sub-pixel electrode SAE5 and the fifth copy pixel electrode CPE5 may be spaced from each other in the diagonal direction with the fourth copy pixel electrode CPE4 interposed therebetween. A plurality of bridge electrodes BAE may connect a pair of the sub-pixel electrode SAE and the copy pixel electrode CPE to each other, and may be disposed to bypass so as not to cross another sub-pixel electrode SAE, another copy pixel electrode CPE, and another bridge electrode BAE.

The first sub-display pixel SDX1 disposed in the first sub-display area SDA1 may include six pixel electrodes including the first to third sub-pixel electrodes SAE1, SAE2, and SAE3 and the first to third copy pixel electrodes CPE1, CPE2, and CPE3, or six emission areas. The second sub-display pixel SDX2 disposed in the second sub-display area SDA2 may include six pixel electrodes including the fourth to sixth sub-pixel electrodes SAE4, SAE5, and SAE6 and the fourth to sixth copy pixel electrodes CPE4, CPE5, and CPE6, or six emission areas. Unlike the main display pixel MDX of the main display area MDA, the sub-display pixel SDX disposed in the sub-display area SDA may have a larger number of emission areas that emit light of the same color. However, the number or density of emission areas per unit area may be larger in the main display pixel MDX than in the sub-display pixel SDX. Further, the number of the light emitting elements that emit light of the first color and the number of light emitting elements that emit light of the third color may be larger in the sub-display pixel SDX than in the main display pixel MDX, but the number of light emitting elements that emit light of the second color may be the same in the sub-display pixel SDX and the main display pixel MDX. Accordingly, in the display device 10, the resolution of the main display area MDA may be higher than that of the sub-display area SDA. The sub-display area SDA may have the resolution lower than that of the main display area MDA in consideration of the transmittance of light incident on the optical device 500 disposed under the sub-display area SDA.

In one or more embodiments, the first sub-pixel circuit SPC1 electrically connected to the first sub-display pixel SDX1 and the second sub-pixel circuit SPC2 electrically connected to the second sub-display pixel SDX2 may be disposed in the first sub-display area SDA1 of the sub-display area SDA. On the other hand, in the second sub-display area SDA2, the pixel circuit may not be disposed, and the plurality of sub-pixel electrodes SAE, the plurality of copy pixel electrodes CPE, the plurality of connection patterns BAP (e.g., see FIG. 11), and bridge patterns BRE1, BRE2, and BRE3 (see FIGS. 11 and 12) that electrically connect them to the second sub-pixel circuit SPC2 may be disposed.

As will be described later, the plurality of sub-pixel electrodes SAE and the plurality of copy pixel electrodes CPE are disposed in the sub-display areas SDA1 and SDA2 of the display device 10, and they may be distinguished depending on the arrangement position and the connection structure. For example, the first to third sub-pixel electrodes SAE1, SAE2, and SAE3 disposed in the first sub-display area SDA1 may be disposed on (e.g., at) the same layer, and may be connected to the first to third copy pixel electrodes CPE1, CPE2, and CPE3 through the first to third bridge electrodes BAE1, BAE2, and BAE3 that are integrated. The sub-pixel electrodes SAE, the copy pixel electrodes CPE, and the bridge electrodes BAE disposed in the first sub-display area SDA1 may constitute substantially the same one electrode, and may have substantially the same material and substantially the same cross-sectional structure. The sub-pixel electrodes SAE and the copy pixel electrodes CPE disposed in the first sub-display area SDA1 may be referred to as a first type sub-pixel electrode SAE #1 (or ‘first sub-pixel electrode’) and a first type copy pixel electrode CPE #1 (or ‘first copy pixel electrode’), respectively.

On the other hand, the fourth to sixth sub-pixel electrodes SAE4, SAE5, and SAE6 disposed in the second sub-display area SDA2 may be connected to the fourth to sixth copy pixel electrodes CPE4, CPE5, and CPE6 through patterns that are disposed on (e.g., at) the same layer but are distinguished. A plurality of connection patterns surrounding the fourth to sixth sub-pixel electrodes SAE4, SAE5, and SAE6 and the fourth to sixth copy pixel electrodes CPE4, CPE5, and CPE6 may be disposed in the second sub-display area SDA2, and the connection patterns may also be distinguished at the valley portion VA of the second pixel defining layer 132 so that different pairs of sub-pixel electrodes and copy pixel electrodes may be electrically insulated. The sub-pixel electrodes SAE and the copy pixel electrodes CPE disposed in the second sub-display area SDA2 may be referred to as a second type sub-pixel electrode SAE #2 (or ‘second sub-pixel electrode’) and a second type copy pixel electrode CPE #2 (or ‘second copy pixel electrode’), respectively.

The first sub-pixel circuit SPC1 may be electrically connected to the first type sub-pixel electrode SAE #1, or the sub-pixel electrodes SAE disposed in the first sub-display pixel SDX1. Each of the plurality of first sub-pixel circuits SPC1 may be electrically connected to the first sub-pixel electrode SAE1, the second sub-pixel electrode SAE2, and the third sub-pixel electrode SAE3. Each of the first type copy pixel electrodes CPE #1 disposed in the first sub-display pixel SDX1 may be electrically connected to the first type sub-pixel electrode SAE #1 through the bridge electrode BAE, and a plurality of light emitting elements including a pair of the sub-pixel electrode SAE and the copy pixel electrode CPE may emit light concurrently (e.g., simultaneously). Each of the sub-pixel electrodes SAE disposed in the first sub-display pixel SDX1 may be disposed to overlap the first sub-pixel circuit SPC1.

The second sub-pixel circuit SPC2 may be electrically connected to the second type sub-pixel electrode SAE #2, or the sub-pixel electrodes SAE disposed in the second sub-display pixel SDX2. Each of the plurality of second sub-pixel circuits SPC2 may be electrically connected to the fourth sub-pixel electrode SAE4, the fifth sub-pixel electrode SAE5, and the sixth sub-pixel electrode SAE6. Each of the second type copy pixel electrodes CPE #2 disposed in the second sub-display pixel SDX2 may be electrically connected to the second type sub-pixel electrode SAE #2 through the connection pattern BAP (e.g., see FIG. 11), and a plurality of light emitting elements including a pair of the sub-pixel electrode SAE and the copy pixel electrode CPE may emit light concurrently (e.g., simultaneously). The connection patterns that connect the second sub-pixel circuit SPC2 and the sub-pixel electrode SAE #2 of the second sub-display pixel SDX2 may be disposed in the sub-display area SDA. At least some of the copy pixel electrodes CPE #1 disposed in the first sub-display pixel SDX1 may be disposed to overlap the second sub-pixel circuit SPC2. Some others of the copy pixel electrodes CPE #1 disposed in the first sub-display pixel SDX1 may be disposed in the area where the sub-pixel circuits SPC1 and SPC2 are not disposed.

In accordance with one or more embodiments, the sub-pixel electrodes SAE #1, the copy pixel electrodes CPE #1, and the bridge electrodes BAE #1 that are disposed in the first sub-display area SDA1 may be disposed on (e.g., at) the same layer to form an integrated pattern. For example, the first to third bridge electrodes BAE1, BAE2, and BAE3, which are the bridge electrodes BAE disposed in the first sub-display area SDA1, may be bridge portions that are integrated with the first to third sub-pixel electrodes SAE1, SAE2, and SAE3 and the first to third copy pixel electrodes CPE1, CPE2, and CPE3. On the other hand, the sub-pixel electrodes SAE #2 and the copy pixel electrodes CPE #2 disposed in the second sub-display area SDA2 may be disposed on (e.g., at) the same layer and have the same electrode structure, but the connection pattern BAP (e.g., see FIG. 11) disposed therearound may contain a different material and have a different structure. The connection pattern BAP disposed in the second sub-display area SDA2 may be disposed on (e.g., at) the same layer as the sub-pixel electrodes SAE #2 and the copy pixel electrodes CPE #2 disposed in the second sub-display area SDA2, and may be electrically connected thereto by the contact therewith.

The sub-pixel electrodes SAE #1 disposed in the first sub-display area SDA1 may be disposed to overlap the first sub-pixel circuit SPC1, and may be integrated with the copy pixel electrode CPE #1 through the bridge electrodes BAE #1 on (e.g., at) the same layer. The sub-pixel electrodes SAE #2 disposed in the second sub-display area SDA2 may be electrically connected to the second sub-pixel circuit SPC2 but may be disposed so as not to overlap the second sub-pixel circuit SPC2. The sub-pixel electrodes SAE #2 disposed in the second sub-display area SDA2 may be electrically connected to the second sub-pixel circuit SPC2 through the bridge electrodes disposed thereunder. A more detailed description thereof will be described later with reference to other drawings.

In the sub-display area SDA, the sub-pixel circuits SPC1 and SPC2 may be disposed only in the first sub-display area SDA1 in consideration of the transmittance. Because the number of sub-pixel circuits SPC1 and SPC2 disposed per unit area is smaller in the sub-display area SDA than in the main display area MDA, the sub-pixel electrode SAE and the copy pixel electrode CPE may form a pair to form a plurality of emission areas in the case of the sub-display pixels SDX1 and SDX2 disposed in the sub-display area SDA.

FIG. 9 is a cross-sectional view showing an example of a main display area of a display device according to one or more embodiments.

FIG. 9 schematically shows a cross section of two light emitting elements EL and the pixel circuits PXC1 and PXC2 disposed in the main display area MDA. FIG. 9 shows a cross section of a part of the first pixel circuit PXC1 and a part of the second pixel circuit PXC2 adjacent to each other.

Referring to FIG. 9, the display panel 100 may include the substrate 110, the circuit layer 120 disposed on the substrate 110, the light emitting element layer 130, and the encapsulation layer 140. The circuit layer 120, the light emitting element layer 130, and the encapsulation layer 140 may be sequentially arranged or stacked on the substrate 110 in the thickness direction (e.g., the third direction DR3).

The substrate 110 may be made of a material having a flexible characteristic capable of bending, folding, rolling, and/or the like. The substrate 110 may be formed of an insulating material such as a polymer resin. For example, the substrate 110 may be made of polyimide.

The circuit layer 120 may include the pixel circuit PXC and wires. For example, the circuit layer 120 may include circuit elements (e.g., the pixel transistors T and the capacitor Cst) constituting the pixel circuit PXC of each main display pixel MDX, and wires (e.g., various power lines and signal lines including the power lines PL, the scan lines SL, the emission control lines ECL, and the data lines DL) electrically connected to the pixel circuit PXC.

Among elements that may be provided on the circuit layer 120, FIG. 9 illustrates a first thin film transistor TFT1 (also referred to as a “first pixel transistor”) included in the pixel circuit PXC of each main display pixel MDX, a second thin film transistor TFT2 (also referred to as a “second pixel transistor”), and a capacitor Cst. The first thin film transistor TFT1 may be first type transistors (e.g., P-type transistors) including a first semiconductor material (e.g., polysilicon) from among the pixel transistors T constituting each of the pixel circuits PXC. For example, the first thin film transistor TFT1 may be one of the first, second, fifth, sixth, and seventh transistors T1, T2, T5, T6, and T7. FIG. 9 illustrates, as the first thin film transistor TFT1, one transistor (e.g., the sixth transistor T6 of FIG. 5) connected to the light emitting element EL through at least one connection electrode (e.g., a first connection electrode CNE1 and a second connection electrode CNE2) from among the first type transistors. The second thin film transistor TFT2 may be second type transistors (e.g., N-type transistors) including a second semiconductor material (e.g., oxide semiconductor) from among the pixel transistors T. For example, the second thin film transistor TFT2 may be one of the third and fourth transistors T3 and T4.

The circuit layer 120 may include semiconductor layers for forming circuit elements, wires, or the like, conductive layers, and insulating layers disposed between and/or around the conductive layers and the semiconductor layers. For example, the circuit layer 120 may include a barrier layer 121, a lower conductive layer BCDL, a buffer layer 122, a first semiconductor layer SCL1 (e.g., a polysilicon semiconductor layer), a first insulating layer 123 (e.g., a first gate insulating layer), a first conductive layer CDL1 (e.g., a first gate conductive layer), a second insulating layer 124 (e.g., a second gate insulating layer), a second conductive layer CDL2 (e.g., a second gate conductive layer), a third insulating layer 125 (e.g., a first interlayer insulating layer), a second semiconductor layer SCL2 (e.g., an oxide semiconductor layer), a fourth insulating layer 126 (e.g., a third gate insulating layer), a third conductive layer CDL3 (e.g., a third gate insulating layer), a fifth insulating layer 127 (e.g., a second interlayer insulating layer), a fourth conductive layer CDL4 (e.g., a first source-drain conductive layer), and a sixth insulating layer 128 (e.g., a first via layer or a first planarization layer) that are sequentially disposed on the substrate 110 with reference to the third direction DR3. In one or more embodiments, the circuit layer 120 may further include an interlayer insulating layer ILD (ILD1, ILD2) on the a fifth insulating layer 127, and a fifth conductive layer CDL5 (e.g., a second source-drain conductive layer) and a seventh insulating layer 129 (e.g., a second via layer or a second planarization layer) sequentially disposed on the sixth insulating layer 128.

The barrier layer 121 may be disposed on the substrate 110. The barrier layer 121 may protect elements disposed on the circuit layer 120 and the light emitting element layer 130 from moisture permeating through the substrate 110 that is susceptible to moisture permeation. The barrier layer 121 may include at least one inorganic layer containing an inorganic insulating material (e.g., silicon nitride, silicon oxide, silicon oxynitride, titanium oxide, aluminum oxide, and/or another inorganic insulating material). The material of the barrier layer 121 may be variously changed according to one or more embodiments.

The lower conductive layer BCDL may be disposed on the barrier layer 121. The lower conductive layer BCDL may include a lower metal layer BML overlapping the active layer (e.g., a first active layer ACT1 and/or a second active layer ACT2) of the at least one pixel transistor T, and/or at least one wire (or a part of the at least one wire). FIG. 9 illustrates that the lower metal layer BML is disposed to overlap only the first active layer ACT1 of the first thin film transistor TFT1 and the capacitor electrodes CAE1 and CAE2 of the capacitor Cst, but the present disclosure is not limited thereto. For example, the lower metal layer BML may be patterned into an appropriate size and/or shape as needed and disposed on a part of the pixel circuit PXC, or may be disposed on the entire surface of the pixel circuit PXC. For example, the lower metal layer BML may be disposed only in a part of the pixel area to overlap the first transistor T1 illustrated in FIG. 5. In one or more embodiments, the lower metal layer BML may also be utilized as a light blocking pattern and/or a back-gate electrode of at least one pixel transistor T, or the like.

The buffer layer 122 may be disposed on the lower conductive layer BCDL to cover the lower conductive layer BCDL. The buffer layer 122 may include at least one inorganic layer containing an inorganic insulating material.

The first thin film transistor TFT1, the second thin film transistor TFT2, and the capacitor Cst may be disposed on one surface of the substrate 110 including the buffer layer 122. The first thin film transistor TFT1 may include the first active layer ACT1 and a first gate electrode G1. The second thin film transistor TFT2 may include the second active layer ACT2 and a second gate electrode G2. In one or more embodiments, the second thin film transistor TFT2 may include a back-gate electrode BG. The capacitor Cst may include a first capacitor electrode CAE1 and a second capacitor electrode CAE2.

The first semiconductor layer SCL1 may be disposed on the buffer layer 122. The first semiconductor layer SCL1 may include the first active layer ACT1 of the first thin film transistor TFT1. For example, the first semiconductor layer SCL1 may include the first active layer ACT1 of each of the first, second, fifth, sixth, and seventh transistors T1, T2, T5, T6, and T7.

The first active layer ACT1 may be provided on the buffer layer 122 and may include a first semiconductor material (e.g., polysilicon). The first active layer ACT1 may include a first channel region CH1, a first source region S1, and a first drain region D1. The first channel region CH1 may overlap the first gate electrode G1 in the third direction DR3. The first source region S1 may be disposed on one side of the first channel region CH1, and the first drain region D1 may be disposed on the other side of the first channel region CH1. The first source region S1 and the first drain region D1 may be regions formed to have conductivity by doping ions or impurities into a semiconductor for forming the first active layer ACT1. In one or more embodiments, the first source region S1 may be a source electrode of the first thin film transistor TFT1. In one or more embodiments, the first thin film transistor TFT1 may include a separate source electrode connected to the first source region S1. In one or more embodiments, the first drain region D1 may be a drain electrode of the first thin film transistor TFT1. In one or more embodiments, the first thin film transistor TFT1 may include a separate drain electrode connected to the first drain region D1.

The first insulating layer 123 may be disposed on the first semiconductor layer SCL1 and the buffer layer 122. The first insulating layer 123 may cover the first semiconductor layer SCL1 and the buffer layer 122.

The first conductive layer CDL1 may be disposed on the first insulating layer 123. The first conductive layer CDL1 may include the first gate electrode G1 of the first thin film transistor TFT1. The first gate electrode G1 may be disposed to overlap a part of the first active layer ACT1 (e.g., the first channel region CH1). In one or more embodiments, the first conductive layer CDL1 may further include at least one wire (or a part of the at least one wire), a conductive pattern (e.g., a bridge pattern), and/or a capacitor electrode. For example, the first conductive layer CDL1 may further include the first capacitor electrode CAE1 of the capacitor Cst.

In one or more embodiments, the first capacitor electrode CAE1 may be integrally formed with the gate electrode of at least one first thin film transistor TFT1. For example, the first capacitor electrode CAE1 may be integrally formed with the gate electrode of the first transistor T1 illustrated in FIGS. 5 and 6. For example, the first capacitor electrode CAE1 and the gate electrode of the first transistor T1 may be formed as one conductive pattern, and the second capacitor electrode CAE2 may be disposed to overlap the conductive pattern.

The second insulating layer 124 may be disposed on the first conductive layer CDL1 and the first insulating layer 123. The second insulating layer 124 may cover the first conductive layer CDL1 and the first insulating layer 123.

The second conductive layer CDL2 may be disposed on the second insulating layer 124. The second conductive layer CDL2 may include one electrode of the capacitor Cst, for example, the second capacitor electrode CAE2. In one or more embodiments, the second conductive layer CDL2 may further include at least one electrode, a wire (or a part of the at least one wire), and/or a conductive pattern (e.g., a bridge pattern). For example, the second conductive layer CDL2 may further include the back-gate electrode BG connected to the second gate electrode G2 of the second thin film transistor TFT2.

The third insulating layer 125 may be disposed on the second conductive layer CDL2 and the second insulating layer 124. The third insulating layer 125 may cover the second conductive layer CDL2 and the second insulating layer 124.

The second semiconductor layer SCL2 may be disposed on the third insulating layer 125. The second semiconductor layer SCL2 may include the second active layer ACT2 of the second thin film transistor TFT2. For example, the second semiconductor layer SCL2 may include the second active layer ACT2 of each of the third and fourth transistors T3 and T4.

The second active layer ACT2 may be provided in the second semiconductor layer SCL2 and may include a second semiconductor material (e.g., an oxide semiconductor) different from the first semiconductor material. For example, the second active layer ACT2 may include IGZO (indium (In), gallium (Ga), zinc (Zn) and oxygen (O)), IGZTO (indium (In), gallium (Ga), zinc (Zn), tin (Sn) and oxygen (O)), or IGTO (indium (In), gallium (Ga), tin (Sn), and/or oxygen (O)).

The second active layer ACT2 may include a second channel region CH2, a second source region S2, and a second drain region D2. The second channel region CH2 may overlap the second gate electrode G2 in the third direction DR3. The second source region S2 may be disposed on one side of the second channel region CH2, and the second drain region D2 may be disposed on the other side of the second channel region CH2. The second source region S2 and the second drain region D2 may be conductive regions by doping ions or impurities into a semiconductor for forming the second active layer ACT2. In one or more embodiments, the second source region S2 may be a source electrode of the second thin film transistor TFT2. In one or more embodiments, the second thin film transistor TFT2 may include a separate source electrode connected to the second source region S2. In one or more embodiments, the second drain region D2 may be a drain electrode of the second thin film transistor TFT2. In one or more embodiments, the second thin film transistor TFT2 may include a separate drain electrode connected to the second drain region D2.

The fourth insulating layer 126 may be disposed on the second semiconductor layer SCL2 and the third insulating layer 125. The fourth insulating layer 126 may cover the second semiconductor layer SCL2 and the third insulating layer 125.

In one or more embodiments, the first insulating layer 123, the second insulating layer 124, the third insulating layer 125, and the fourth insulating layer 126 may be an inorganic insulating layer including an inorganic insulating material (e.g., silicon nitride, silicon oxide, silicon oxynitride, titanium oxide, aluminum oxide, and/or another inorganic insulating material), and may each have a single layer or multilayer structure. At least two insulating layers from among the first insulating layer 123, the second insulating layer 124, the third insulating layer 125, and the fourth insulating layer 126 may include the same material or may include different materials. Materials of each of the first insulating layer 123, the second insulating layer 124, the third insulating layer 125, and the fourth insulating layer 126 may be variously changed according to one or more embodiments.

The third conductive layer CDL3 may be disposed on the fourth insulating layer 126. The third conductive layer CDL3 may include the second gate electrode G2 of the second thin film transistor TFT2. The second gate electrode G2 may be disposed to overlap a part of the second active layer ACT2 (e.g., the second channel region CH2). In one or more embodiments, the third conductive layer CDL3 may further include at least one wire (or a part of the at least one wire), a conductive pattern (e.g., a bridge pattern), and/or a capacitor electrode.

In one or more embodiments, each of the electrodes, the conductive patterns, and/or the wires provided in the lower conductive layer BCDL, the first conductive layer CDL1, the second conductive layer CDL2, and the third conductive layer CDL3 may include a conductive material (e.g., molybdenum (Mo), aluminum (Al), chromium (Cr), gold (Au), titanium (Ti), nickel (Ni), neodymium (Nd), copper (Cu), and/or at least one of other metals, alloys thereof, or other conductive materials), and may each have a single layer or multilayer structure. For example, each of the electrodes, the conductive patterns, and/or the wires provided in the lower conductive layer BCDL, the first conductive layer CDL1, the second conductive layer CDL2, and the third conductive layer CDL3 may include molybdenum (Mo) or other metal materials. At least two conductive layers from among the lower conductive layer BCDL, the first conductive layer CDL1, the second conductive layer CDL2, and the third conductive layer CDL3 may include the same material or may include different materials. Materials of each of the lower conductive layer BCDL, the first conductive layer CDL1, the second conductive layer CDL2, and the third conductive layer CDL3 are not limited, and may be variously changed according to one or more embodiments.

The fifth insulating layer 127 may be disposed on the third conductive layer CDL3 and the fourth insulating layer 126. The fifth insulating layer 127 may cover the third conductive layer CDL3 and the fourth insulating layer 126.

The fourth conductive layer CDL4 may be disposed on the fifth insulating layer 127. The fourth conductive layer CDL4 may include the first connection electrode CNE1 (or a drain electrode of the first thin film transistor TFT1), a first conductive pattern BE1 (or a source electrode of the second thin film transistor TFT2), and a second conductive pattern BE2 (or a drain electrode of the second thin film transistor TFT2). The first connection electrode CNE1 may be provided on the fourth conductive layer CDL4 and may be connected to the first drain region D1 of the first active layer ACT1 through a first contact hole CT1 penetrating the first insulating layer 123, the second insulating layer 124, the third insulating layer 125, the fourth insulating layer 126, and the fifth insulating layer 127. The first conductive pattern BE1 may be provided on the fourth conductive layer CDL4 and may be connected to the second source region S2 of the second active layer ACT2 through a second contact hole CT2 penetrating the fourth insulating layer 126 and the fifth insulating layer 127. The second conductive pattern BE2 may be connected to the second drain region D2 of the second active layer ACT2 through a third contact hole CT3 penetrating the fourth insulating layer 126 and the fifth insulating layer 127. In one or more embodiments, the fourth conductive layer CDL4 may further include at least one wire (or a part of the at least one wire), and/or a conductive pattern (e.g., a bridge pattern). For example, the fourth conductive layer CDL4 may include a part of the power line PL (e.g., the first pixel power line VDL and/or the second pixel power line VSL) provided inside and/or outside the display area DA.

The first interlayer insulating layer ILD1 and the second interlayer insulating layer ILD2 may be disposed on the fourth conductive layer CDL4 and the fifth insulating layer 127. The first interlayer insulating layer ILD1 may cover the fourth conductive layer CDL4 and the fifth insulating layer 127, and the second interlayer insulating layer ILD2 may be disposed on the first interlayer insulating layer ILD1. The first interlayer insulating layer ILD1 and the second interlayer insulating layer ILD2 may also be disposed in the sub-display area SDA to form a layer where the plurality of bridge patterns BRE1, BRE2, and BRE3 disposed in the sub-display area SDA are disposed. The first interlayer insulating layer ILD1 and the second interlayer insulating layer ILD2 may contain an inorganic insulating material, and may replace the sixth insulating layer 128 and the seventh insulating layer 129 that are not disposed in the sub-display area SDA to cover lower layers disposed in the sub-display area SDA.

The sixth insulating layer 128 may be disposed on the second interlayer insulating layer ILD2. The sixth insulating layer 128 may cover the second interlayer insulating layer ILD2.

The fifth conductive layer CDL5 may be disposed on the sixth insulating layer 128. The fifth conductive layer CDL5 may include the second connection electrode CNE2. The second connection electrode CNE2 may be provided in the fifth conductive layer CDL5 and may be connected to the first connection electrode CNE1 through a fourth contact hole CT4 (or a first via hole) penetrating the sixth insulating layer 128, the second interlayer insulating layer ILD2, and the first interlayer insulating layer ILD1. In one or more embodiments, the fifth conductive layer CDL5 may further include at least one wire (or a part of the at least one wire), and/or a conductive pattern (e.g., a bridge pattern). For example, the fifth conductive layer CDL5 may include a part of the power line PL (e.g., the first pixel power line VDL and/or the second pixel power line VSL) provided inside and/or outside the display area DA.

In one or more embodiments, each of the electrodes, the conductive patterns, and/or the wires provided in the fourth conductive layer CDL4 and the fifth conductive layer CDL5 may include a conductive material (e.g., molybdenum (Mo), aluminum (Al), chromium (Cr), gold (Au), titanium (Ti), nickel (Ni), neodymium (Nd), copper (Cu), and at least one of other metals, alloys thereof, or other conductive materials), and may have a single layer or multilayer structure. For example, each of the electrodes, the conductive patterns, and/or the wires provided in the fourth conductive layer CDL4 and the fifth conductive layer CDL5 may be formed of a triple layer structure of titanium/aluminum/titanium (Ti/Al/Ti). The fourth conductive layer CDL4 and the fifth conductive layer CDL5 may include the same material or may include different materials. Materials of each of the fourth conductive layer CDL4 and the fifth conductive layer CDL5 may be variously changed according to one or more embodiments.

The seventh insulating layer 129 may be disposed on the fifth conductive layer CDL5 and the sixth insulating layer 128. The seventh insulating layer 129 may cover the fifth conductive layer CDL5 and the sixth insulating layer 128.

In one or more embodiments, the sixth insulating layer 128 and the seventh insulating layer 129 may be an organic insulating layer including an organic insulating material (e.g., acrylic resin, epoxy resin, phenolic resin, polyamide resin, polyimide resin, and/or other organic insulating material) to planarize the circuit layer 120, and may each have a single layer or multilayer structure. The sixth insulating layer 128 and the seventh insulating layer 129 may include the same material or may include different materials. Materials of each of the sixth insulating layer 128 and the seventh insulating layer 129 may be variously changed according to one or more embodiments.

The light emitting element layer 130 may include the first pixel defining layer 131 that partitions the emission areas EA of the pixels PX and the respective light emitting elements EL positioned in the respective emission areas EA. In one or more embodiments, the light emitting element layer 130 may further include a spacer SPC disposed on a part of the first pixel defining layer 131.

Each light emitting element EL may include the pixel electrode AE (e.g., an anode electrode) connected to at least one transistor T (e.g., the first thin film transistor TFT1) included in the main display pixel MDX through the first connection electrode CNE1 and/or the second connection electrode CNE2, and a light emitting layer EML and a common electrode CE (e.g., a cathode electrode) that are sequentially disposed on the pixel electrode AE (e.g., AE: AE1, AE2, AE3). In one or more embodiments, the light emitting element EL may further include a first intermediate layer (e.g., hole layer including a hole transport layer) interposed between the pixel electrode AE and the light emitting layer EML, and a second intermediate layer (e.g., an electron layer including an electron transport layer) interposed between the light emitting layer EML and the common electrode CE.

The pixel electrode AE of the light emitting element EL may include a conductive material and may be disposed on the circuit layer 120. For example, the pixel electrode AE may be disposed on the seventh insulating layer 129 to correspond to each emission area EA. The pixel electrode AE may be connected to the second connection electrode CNE2 through a fifth contact hole CT5 (or a second via hole) penetrating the seventh insulating layer 129.

In one or more embodiments, the pixel electrode AE may include a metallic material having high reflectivity. For example, the pixel electrode AE may have a single layer structure of molybdenum (Mo), titanium (Ti), copper (Cu), and/or aluminum (Al), or may have a multilayer structure (e.g., ITO/Mg, ITO/MgF, ITO/Ag, and ITO/Ag/ITO) including indium-tin-oxide (ITO), indium-zinc-oxide (IZO), zinc oxide (ZnO), indium oxide (In₂O₃) and silver (Ag), magnesium (Mg), aluminum (Al), platinum (Pt), lead (Pb), gold (Au), and/or nickel (Ni).

The light emitting layer EML of the light emitting element EL may include a high molecular material or a low molecular material. In one or more embodiments, the light emitting layer EML may be disposed for each of the pixel electrodes AE1, AE2, and AE3 of each main display pixel MDX, and each light emitting layer EML may emit light of a color corresponding to the corresponding emission area EA. In one or more embodiments, the light emitting layer EML may be a common layer shared by the emission areas EA of different colors, and a wavelength conversion layer and/or color filters corresponding to the color (or wavelength band) of light desired to be emitted from each sub-pixel SPX may be arranged in the emission areas EA of at least some of the sub-pixels SPX.

The common electrode CE of the light emitting element EL includes a conductive material and may be connected to the second pixel power line VSL. In one or more embodiments, the common electrode CE may be a common layer formed across the entire display area DA to cover the light emitting layer EML and the first pixel defining layer 131. The common electrode CE may be disposed across the entire main display area MDA and the entire sub-display area SDA. In one or more embodiments, the common electrode CE may be formed of a transparent conductive material (TCO) such as ITO or IZO capable of transmitting light or a semi-transmissive conductive material such as magnesium (Mg), silver (Ag), or an alloy of magnesium (Mg) and silver (Ag). When the common electrode CE is made of a semi-transmissive conductive material, an improvement in light output efficiency due to a micro cavity effect may be expected.

The first pixel defining layer 131 may have an opening corresponding to each of the emission areas EA and may be around (e.g., may surround) the emission areas EA. For example, the first pixel defining layer 131 may be formed to cover the edge of the pixel electrode AE of each of the light emitting elements EL and may include an opening that exposes the remaining portion of the pixel electrode AE. A region where the exposed pixel electrode AE and the light emitting layer EML overlap (or a region including the same) may be defined as the emission area EA of each main display pixel MDX.

In one or more embodiments, the first pixel defining layer 131 may include at least one organic layer containing an organic insulating material. For example, the first pixel defining layer 131 may include acrylic resin, epoxy resin, phenolic resin, polyamide resin, polyimide resin, unsaturated polyester resin, polyphenylene ether resin, polyphenylenesulfide resin, benzocyclobutene (BCB), and/or other organic insulating materials.

The spacer SPC may be disposed on a part of the first pixel defining layer 131. The spacer SPC may include at least one organic layer containing an organic insulating material. The spacer SPC may include the same material as the first pixel defining layer 131 or may include a different material from the first pixel defining layer 131. In one or more embodiments, the first pixel defining layer 131 and the spacer SPC may be sequentially formed through separate mask processes. In one or more embodiments, the first pixel defining layer 131 and the spacer SPC may be concurrently (e.g., simultaneously) formed using a halftone mask. In this case, the first pixel defining layer 131 and the spacer SPC may be integrated with each other and regarded as a single insulating layer. The organic insulating material constituting the spacer SPC is not particularly limited and may be variously changed according to one or more embodiments.

The encapsulation layer 140 may be disposed on the light emitting element layer 130 in the main region MA. For example, the encapsulation layer 140 may be disposed in the display area DA and the non-display area NA to cover the light emitting element layer 130. The encapsulation layer 140 may block the permeation of oxygen or moisture into the light emitting element layer 130, and may reduce electrical or physical impacts to the circuit layer 120 and the light emitting element layer 130.

In one or more embodiments, the encapsulation layer 140 may include a first inorganic encapsulation layer 141, an organic encapsulation layer 142, and a second inorganic encapsulation layer 143 sequentially disposed on the light emitting element layer 130. The first inorganic encapsulation layer 141 and the second inorganic encapsulation layer 143 may include an inorganic material, and the organic encapsulation layer 142 may include an organic material.

In one or more embodiments, the touch sensing layer TSU and the color filter layer CFL described above with reference to FIG. 3 may be disposed on the encapsulation layer 140.

FIGS. 10 and 11 are cross-sectional views showing an example of a sub-display area of a display device according to one or more embodiments. FIGS. 10 and 11 show the cross section of the light emitting elements EL disposed in the first sub-display area SDA1 and the second sub-display area SDA2 and the electrical connection structure of the light emitting elements EL and the first sub-pixel circuit SPC1 and the second sub-pixel circuit SPC2, respectively. FIG. 10 illustrates the cross-sectional structure of the portion where the first sub-pixel electrode SAE1 and the first copy pixel electrode CPE1 are disposed, and FIG. 11 illustrates the structure of the portion where the fourth sub-pixel electrode SAE4 and the fourth copy pixel electrode CPE4 are disposed.

Referring to FIGS. 10 and 11, the display device 10 may include the first sub-pixel circuit SPC1 and the second sub-pixel circuit SPC2 disposed in the first sub-display area SDA1. Each of the first sub-pixel circuit SPC1 and the second sub-pixel circuit SPC2 may include elements formed by wires and patterns of the first to fifth conductive layers CDL1, CDL2, CDL3, CDL4, and CDL5 the first semiconductor layer SCL1, and the second semiconductor layer SCL2 that are disposed on the substrate 110. The structure and connection of the first sub-pixel circuit SPC1 and the second sub-pixel circuit SPC2 may be the same as the structure of the pixel circuit PXC described above with reference to FIG. 9. Accordingly, detailed descriptions thereof are omitted hereinafter.

The display device 10 may include a third interlayer insulating layer ILD3 disposed in the second sub-display area SDA2. The first interlayer insulating layer ILD1 and the second interlayer insulating layer ILD2 may be disposed in the entire display area DA, and the third interlayer insulating layer ILD3 may be disposed on the second interlayer insulating layer ILD2 in the second sub-display area SDA2. The third interlayer insulating layer ILD3 may be disposed over the entire second sub-display area SDA2 and may be disposed to extend to the vicinity of the boundary between the first sub-display area SDA1 and the second sub-display area SDA2.

In the display device 10, the sixth insulating layer 128 and the seventh insulating layer 129 containing an organic insulating material may be disposed to improve the transmittance in the second sub-display area SDA2. The sixth insulating layer 128 and the seventh insulating layer 129 are disposed over the entire main display area MDA and the entire first sub-display area SDA1, but may be partially disposed only at the vicinity of the boundary with the first sub-display area SDA1 in the second sub-display area SDA2. The sixth insulating layer 128 and the seventh insulating layer 129 may not be disposed at least in the area where the light emitting elements EL of the second sub-display area SDA2 are disposed, or the area where the sub-pixel electrode SAE and the copy pixel electrode CPE are disposed. The second sub-display area SDA2 may have high transmittance because the sixth insulating layer 128 and the seventh insulating layer 129 containing an organic insulating material are not disposed therein, and the amount of light incident on the component disposed in the second sub-display area SDA2, or on the optical device 500 may be increased.

In the display device 10, in the main display area MDA and the first sub-display area SDA1, the seventh insulating layer 129 containing an organic insulating material may be disposed under the anode electrode of the light emitting element EL to serve as a via layer, but in the second sub-display area SDA2, the first to third interlayer insulating layers ILD1, ILD2, and ILD3 containing an inorganic insulating material may be disposed under the anode electrode of the light emitting element EL to serve as a via layer.

The first sub-pixel circuit SPC1 disposed in the first sub-display area SDA1 may be electrically connected to the first sub-pixel electrode SAE1. The first connection electrode CNE1 of the first sub-pixel circuit SPC1 may be connected to the second connection electrode CNE2 disposed on the sixth insulating layer 128, and the second connection electrode CNE2 thereof may be connected to the first sub-pixel electrode SAE1 disposed on the seventh insulating layer 129. The first sub-pixel electrode SAE1 may be disposed to overlap the first sub-pixel circuit SPC1, and may be electrically connected thereto to become the anode electrode of the light emitting element EL. The first sub-pixel electrode SAE1 may overlap the opening of the first pixel defining layer 131, and may constitute the light emitting element EL together with the light emitting layer EML disposed at the opening, and the common electrode CE disposed on the light emitting layer EML.

The first copy pixel electrode CPE1 disposed in the first sub-display area SDA1 may be electrically connected to the first sub-pixel electrode SAE1. In one or more embodiments, the first copy pixel electrode CPE1 may be integrated with the first sub-pixel electrode SAE1 through the first bridge electrode BAE1 disposed on (e.g., at) the same layer. Each of the first copy pixel electrode CPE1 and the first bridge electrode BAE1 may be directly disposed on the seventh insulating layer 129. The first copy pixel electrode CPE1 may be disposed to overlap the second sub-pixel circuit SPC2, but may be electrically connected to the first sub-pixel circuit SPC1 through the first sub-pixel electrode SAE1. The first copy pixel electrode CPE1 may overlap the opening of the first pixel defining layer 131, and may constitute the light emitting element EL together with the light emitting layer EML disposed at the opening and the common electrode CE disposed on the light emitting layer EML. An electrical signal for light emission of the light emitting element EL may be concurrently (e.g., simultaneously) applied to the first sub-pixel electrode SAE1 and the first copy pixel electrode CPE1, and the light emitting elements EL including each of them may emit light concurrently (e.g., simultaneously). The light emitting layers EML disposed on the first sub-pixel electrode SAE1 and the first copy pixel electrode CPE1 may be light emitting layers that emit light of the same color.

The second sub-pixel circuit SPC2 disposed in the first sub-display area SDA1 may be electrically connected to any one of the fourth to sixth sub-pixel electrodes SAE4, SAE5, and SAE6 disposed in the second sub-display area SDA2. The pixel circuit may not be disposed in the second sub-display area SDA2, and the second sub-display area SDA2 may include a plurality of patterns and electrodes capable of transmitting the electrical signal of the second sub-pixel circuit SPC2.

In accordance with one or more embodiments, the display device 10 may include the plurality of bridge patterns BRE1, BRE2, and BRE3 disposed in the sub-display areas SDA1 and SDA2. The bridge patterns BRE1, BRE2, and BRE3 may be disposed on the first interlayer insulating layer ILD1 or the second interlayer insulating layer ILD2 disposed over the entire display area DA. The bridge patterns BRE1, BRE2, and BRE3 may transmit the emission signal applied from the second sub-pixel circuit SPC2 to the sub-pixel electrodes SAE disposed in the second sub-display area SDA2.

For example, the bridge patterns BRE1, BRE2, and BRE3 may include a first bridge pattern BRE1, a second bridge pattern BRE2, and a third bridge pattern BRE3 that are disposed on the first interlayer insulating layer ILD1 or the second interlayer insulating layer ILD2. For example, the first bridge pattern BRE1 and the second bridge pattern BRE2 may be disposed on the second interlayer insulating layer ILD2, and the third bridge pattern BRE3 may be disposed on the first interlayer insulating layer ILD1. The third bridge pattern BRE3 may be disposed between the first interlayer insulating layer ILD1 and the second interlayer insulating layer ILD2, and the first bridge pattern BRE1 and the second bridge pattern BRE2 may be disposed between the second interlayer insulating layer ILD2 and the third interlayer insulating layer ILD3. In one or more embodiments, each of the first to third bridge patterns BRE1, BRE2, and BRE3 may contain a transparent conductive material (TCO) such as ITO and/or IZO.

The first bridge pattern BRE1 and the third bridge pattern BRE3 may be electrodes that transmit the emission signal from the second sub-pixel circuit SPC2, and the second bridge pattern BRE2 may be an electrode that connects the third bridge pattern BRE3 disposed on another interlayer insulating layer and the sub-pixel electrode SAE disposed thereon.

For example, the first bridge pattern BRE1 may be disposed on the second interlayer insulating layer ILD2 and electrically connected to the second sub-pixel circuit SPC2 of the first sub-display area SDA1. The first bridge pattern BRE1 may be connected to the third connection electrode CNE3 through a sixth contact hole CT6 penetrating the first interlayer insulating layer ILD1 and the second interlayer insulating layer ILD2. The first bridge pattern BRE1 may extend from the first sub-display area SDA1 to the second sub-display area SDA2, and may be connected to the sub-pixel electrode, e.g., the fourth sub-pixel electrode SAE4, in the second sub-display area SDA2. The fourth sub-pixel electrode SAE4 may be disposed on the third interlayer insulating layer ILD3, and may be connected to the first bridge pattern BRE1 through a seventh contact hole CT7 penetrating the third interlayer insulating layer ILD3.

The third bridge pattern BRE3 may be disposed on the first interlayer insulating layer ILD1 and electrically connected to the second sub-pixel circuit SPC2 of the first sub-display area SDA1. In one or more embodiments, the third bridge pattern BRE3 may be connected to the third connection electrode CNE3 of the second sub-pixel circuit SPC2 through a contact hole penetrating the first interlayer insulating layer ILD1. The third bridge pattern BRE3 may extend from the first sub-display area SDA1 to the second sub-display area SDA2, and may be connected to the second bridge pattern BRE2 disposed on the second interlayer insulating layer ILD2 in the second sub-display area SDA2. The second bridge pattern BRE2 may be disposed on the second interlayer insulating layer ILD2, and may be connected to the third bridge pattern BRE3 through an eighth contact hole CT8 penetrating the second interlayer insulating layer ILD2. The second bridge pattern BRE2 may be connected to the sub-pixel electrode, e.g., the fifth sub-pixel electrode SAE5, in the second sub-display area SDA2. The fifth sub-pixel electrode SAE5 may be disposed on the third interlayer insulating layer ILD3, and may be connected to the second bridge pattern BRE2 through a contact hole penetrating the third interlayer insulating layer ILD3 The second sub-pixel circuit SPC2 disposed in the first sub-display area SDA1 may be electrically connected to the sub-pixel electrodes SAE4, SAE5, and SAE6 of the second sub-display area SDA2 through the first to third bridge patterns BRE1, BRE2, and BRE3. The number and arrangement of the bridge patterns BRE1, BRE2, and BRE3 disposed in the sub-display areas SDA1 and SDA2 may be designed to correspond to the number and arrangement of the second sub-pixel circuit SPC2 and the number and arrangement of the sub-pixel electrode SAE of the second sub-pixel area SDA2. The fourth to sixth sub-pixel electrodes SAE4, SAE5, and SAE6 disposed in the second sub-display area SDA2 may be electrically connected to the second sub-pixel circuit SPC2 through the bridge patterns BRE1, BRE2, and BRE3 without overlapping the second sub-pixel circuit SPC2, and may become the anode electrodes of the light emitting elements EL disposed in the second sub-display area SDA2.

The fourth to sixth sub-pixel electrodes SAE4, SAE5, and SAE6 and the fourth to sixth copy pixel electrodes CPE4, CPE5, and CPE6 may each be disposed on the third interlayer insulating layer ILD3 in the second sub-display area SDA2. The fourth to sixth sub-pixel electrodes SAE4, SAE5, and SAE6 may overlap and may be in contact with any one of the first bridge pattern BRE1 and the second bridge pattern BRE2. The fourth to sixth copy pixel electrodes CPE4, CPE5, and CPE6 do not necessarily overlap the first to third bridge patterns BRE1, BRE2, and BRE3, but may be disposed to overlap them in some cases. The fourth to sixth copy pixel electrodes CPE4, CPE5, and CPE6 are not in direct contact with the first to third bridge patterns BRE1, BRE2, and BRE3, but may be electrically connected to the second sub-pixel circuit SPC2 through the connection pattern BAP to be described later and any one of the fourth to sixth sub-pixel electrodes SAE4, SAE5, and SAE6.

The fourth to sixth sub-pixel electrodes SAE4, SAE5, and SAE6 and the fourth to sixth copy pixel electrodes CPE4, CPE5, and CPE6 may perform the same functions as those of the sub-pixel electrodes and the copy pixel electrodes disposed in the first sub-display area SDA1. For example, the fourth to sixth sub-pixel electrodes SAE4, SAE5, and SAE6 and the fourth to sixth copy pixel electrodes CPE4, CPE5, and CPE6 may serve as the anode electrodes of the light emitting elements EL disposed in the second sub-display area SDA2. The light emitting elements EL, each including one of the fourth to sixth sub-pixel electrodes SAE4, SAE5, and SAE6 and the fourth to sixth copy pixel electrodes CPE4, CPE5, and CPE6 that are electrically connected to each other, may emit light concurrently (e.g., simultaneously).

In accordance with one or more embodiments, the display device 10 may include the second pixel defining layer 132 and the connection pattern BAP disposed in the second sub-display area SDA2. The connection pattern BAP and the second pixel defining layer 132 may have a stacked structure on the third interlayer insulating layer ILD3, and may have substantially the same planar pattern. For example, the connection pattern BAP and the second pixel defining layer 132 may be disposed substantially over the entire second sub-display area SDA2 except for some areas. The connection pattern BAP and the second pixel defining layer 132 may be disposed to partially expose the plurality of sub-pixel electrodes SAE4, SAE5, and SAE6 and the plurality of copy pixel electrodes CPE4, CPE5, and CPE6 of the second sub-display area SDA2.

The connection pattern BAP and the second pixel defining layer 132 may not be disposed in the valley portion VA formed to be around (e.g., to surround) a pair of one of the sub-pixel electrodes SAE4, SAE5, and SAE6 and one of the copy pixel electrodes CPE4, CPE5, and CPE6. The valley portion VA may be an area where the connection pattern BAP and the second pixel defining layer 132 are not substantially disposed. For example, the valley portion VA may be around (e.g., may surround) one fourth sub-pixel electrode SAE4 and one fourth copy pixel electrode CPE4. Further, the valley portion VA may be around (e.g., may surround) one fifth sub-pixel electrode SAE5 and one fifth copy pixel electrode CPE5, and may surround one sixth sub-pixel electrode SAE6 and one sixth copy pixel electrode CPE6. The valley portion VA may have an atypical pattern shape in the second sub-display area SDA2, and may have a partially closed loop shape while being around (e.g., surrounding) a pair of one of the sub-pixel electrodes SAE4, SAE5, and SAE6 and one of the copy pixel electrodes CPE4, CPE5, and CPE6.

In the second sub-display area SAD2, the connection pattern BAP and the second pixel defining layer 132 may be disposed in the area other than the area where the valley portion VA is located. In the area surrounded by the valley portion VA, the connection pattern BAP may be disposed on (e.g., at) the same layer as the sub-pixel electrodes SAE4, SAE5, and SAE6 and the copy pixel electrodes CPE4, CPE5, and CPE6, and a pair of one of the sub-pixel electrodes SAE4, SAE5, and SAE6 and one of the copy pixel electrodes CPE4, CPE5, and CPE6 may be connected to each other through the connection pattern BAP. Hereinafter, the cross-sectional structure of the second pixel defining layer 132 and the pixel electrodes and the connection pattern BAP disposed in the second sub-display area SDA2 will be described in more detail with reference to other drawings.

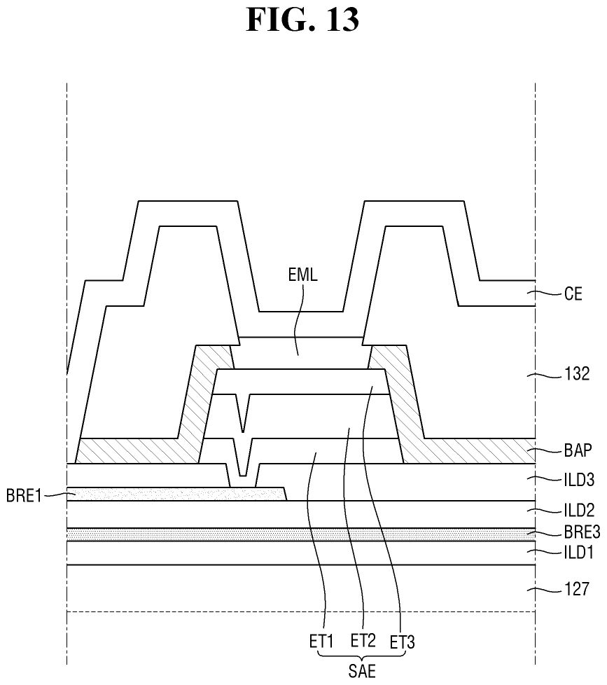

FIG. 12 is a cross-sectional view showing the connection between pixel electrodes and connection patterns disposed in a second sub-display area of a display device according to one or more embodiments. FIG. 13 is a cross-sectional view specifically showing the connection between the pixel electrode and the connection pattern disposed in the second sub-display area of FIG. 12.

Referring to FIGS. 12 and 13 in addition to FIGS. 9 and 11, the connection pattern BAP may be disposed on the third interlayer insulating layer ILD3. The connection pattern BAP may be disposed on (e.g., at) the same layer as the sub-pixel electrodes SAE4, SAE5, and SAE6 and the copy pixel electrodes CPE4, CPE5, and CPE6 of the second sub-display area SDA2, and may be partially disposed on the sub-pixel electrodes SAE4, SAE5, and SAE6 and the copy pixel electrodes CPE4, CPE5, and CPE6. For example, the connection patterns BAP may partially cover and may be in contact with the side surfaces and the top surfaces of the sub-pixel electrodes SAE4, SAE5, and SAE6 and the copy pixel electrodes CPE4, CPE5, and CPE6. The light emitting layer EML may be disposed on a part of the top surfaces of the sub-pixel electrodes SAE4, SAE5, and SAE6 and the copy pixel electrodes CPE4, CPE5, and CPE6 where the connection pattern BAP is not disposed.

In one or more embodiments, the connection pattern BAP may transmit light and may include a material that has electrical conductivity. For example, the connection pattern BAP may include at least one of IZO, IGZO, ITGZO, ITO, ITZO, ITGO, and/or IGO.

The second pixel defining layer 132 may be disposed on the connection pattern BAP. The second pixel defining layer 132 may be disposed on the entire connection pattern BAP, and may expose a part of the top surfaces of the sub-pixel electrodes SAE4, SAE5, and SAE6 and the copy pixel electrodes CPE4, CPE5, and CPE6 while partially overlapping them. For example, the second pixel defining layer 132 may include a plurality of openings to expose the sub-pixel electrodes SAE4, SAE5, and SAE6 and the copy pixel electrodes CPE4, CPE5, and CPE6, and the light emitting layer EML forming the light emitting element EL may be disposed on the sub-pixel electrodes SAE4, SAE5, and SAE6 and the copy pixel electrodes CPE4, CPE5, and CPE6 in the opening of the second pixel defining layer 132.

According to one or more embodiments, the second pixel defining layer 132 may include an inorganic insulating material. For example, the second pixel defining layer 132 may include aluminum oxide, titanium oxide, tantalum oxide, hafnium oxide, zinc oxide, silicon oxide, silicon nitride, and/or silicon oxynitride. In the display device 10, the first pixel defining layer 131 containing an organic insulating material may be disposed in the main display area MDA and the first sub-display area SDA1, and the second pixel defining layer 132 containing an inorganic insulating material may be disposed in the second sub-display area SDA2. The second pixel defining layer 132 that is thin may be disposed in the second sub-display area SDA2 to ensure light transmittance.

In accordance with one or more embodiments, the second pixel defining layer 132 may be spaced from the top surfaces of the sub-pixel electrodes SAE4, SAE5, and SAE6 and the copy pixel electrodes CPE4, CPE5, and CPE6. The second pixel defining layer 132 may not be in direct contact with the sub-pixel electrodes SAE4, SAE5, and SAE6 and the copy pixel electrodes CPE4, CPE5, and CPE6 while partially overlapping them, and the connection patterns BAP may be disposed between the second pixel defining layer 132 and the sub-pixel electrodes SAE4, SAE5, and SAE6 and the copy pixel electrodes CPE4, CPE5, and CPE6. The connection patterns BAP may be disposed in substantially the same pattern under the second pixel defining layer 132, and may be disposed to be recessed from the inner sidewall of the second pixel defining layer 132 at the opening of the second pixel defining layer 132. Spaces where the connection patterns BAP are recessed inward may be formed between the bottom surface of the second pixel defining layer 132 and the top surfaces of the sub-pixel electrodes SAE4, SAE5, and SAE6 and the copy pixel electrodes CPE4, CPE5, and CPE6. The light emitting layer EML may be disposed in the opening of the second pixel defining layer 132, and the spaces formed by the second pixel defining layer 132, the connection pattern BAP, and the pixel electrodes may be filled with the light emitting layer EML.

The shape of the connection pattern BAP may be formed by partial removal of the portion disposed under the second pixel defining layer 132 in a process of removing the layer that has been formed to completely cover the third interlayer insulating layer ILD3 and the pixel electrodes along the opening of the second pixel defining layer 132.

In accordance with one or more embodiments, the second pixel defining layer 132 may include the valley portion VA that does not overlap the pixel electrodes of the second sub-display area SDA2 but exposes the layer thereunder, and the connection pattern BAP may not be disposed at the valley portion VA. The second pixel defining layer 132 and the connection pattern BAP disposed on both sides of the valley portion VA may be spaced from each other. Even at the valley portion VA of the second pixel defining layer 132, the connection pattern BAP may be recessed inward from the bottom surface of the second pixel defining layer 132, and the third interlayer insulating layer ILD3 may be exposed. The shape of the connection pattern BAP at the valley portion VA of the second pixel definition layer 132 may also be a structure formed by further etching a part of the connection pattern BAP disposed under the second pixel definition layer 132.

Accordingly, the connection pattern BAP may be completely separated from another connection pattern BAP disposed on the opposite side with respect to the valley portion VA. The connection pattern BAP is partially removed at the valley portion VA and the opening of the second pixel defining layer 132, but may have a single pattern shape in the area surrounded by the closed loop-shaped valley portion VA. The connection pattern BAP disposed in the area surrounded by the valley portion VA may be connected to one of the sub-pixel electrodes SAE4, SAE5, and SAE6 and at least one of the copy pixel electrodes CPE4, CPE5, and CPE6. For example, the fourth sub-pixel electrode SAE4 and the fourth copy pixel electrode CPE4 may be disposed in the area surrounded by the valley portion VA, and may each be in contact with one connection pattern BAP disposed in the area surrounded by the valley portion VA. Each of the fifth sub-pixel electrode SAE5 and the fifth copy pixel electrode CPE5 may also be in contact with one connection pattern BAP disposed in the area surrounded by the valley portion VA. Because, however, the connection patterns BAP disposed in different areas surrounded by the valley portion VA are completely separated at the valley portion VA, the fourth sub-pixel electrode SAE4 may not be connected to the fifth sub-pixel electrode SAE5 and the fifth copy pixel electrode CPE5. A pair of one of the sub-pixel electrodes SAE4, SAE5, and SAE6 and one of the copy pixel electrodes CPE4, CPE5, and CPE6 disposed together in the area surrounded by the valley portion VA in the second sub-display area SDA2 may be electrically connected to each other and driven concurrently (e.g., simultaneously). On the other hand, the sub-pixel electrodes SAE4, SAE5, and SAE6 disposed in different areas surrounded by the valley portion VA may be driven individually.

The second sub-pixel circuit SPC2 disposed in the first sub-display area SDA1 may be electrically connected to the fourth sub-pixel electrode SAE4. The third connection electrode CNE3 of the second sub-pixel circuit SPC2 may be connected to the first bridge pattern BRE1 disposed on the second interlayer insulating layer ILD2 through the sixth contact hole CT6, and the first bridge pattern BRE1 may be in contact with the fourth sub-pixel electrode SAE4 through the seventh contact hole CT7 penetrating the third interlayer insulating layer ILD3. Alternatively, the third connection electrode CNE3 may be connected to the third bridge pattern BRE3 disposed on the first interlayer insulating layer ILD1 through another contact hole, and the third bridge pattern BRE3 may be connected to the second bridge pattern BRE2 through the eighth contact hole CT8 penetrating the second interlayer insulating layer ILD2. The second bridge pattern BRE2 may be in contact with the fifth sub-pixel electrode SAE5 disposed on the third interlayer insulating layer ILD3. FIG. 11 illustrates a structure in which the second sub-pixel circuit SPC2 is electrically connected to the fourth sub-pixel electrode SAE4, and the second sub-pixel circuit SPC2 that is not shown in the drawing may be connected to the fifth sub-pixel electrode SAE5.

The fourth copy pixel electrode CPE4 disposed in the second sub-display area SDA2 may be electrically connected to the fourth sub-pixel electrode SAE4. As described above, the fourth copy pixel electrode CPE4 may be electrically connected to the fourth sub-pixel electrode SAE4 through the connection pattern BAP. The fourth sub-pixel electrode SAE4 and the fourth copy pixel electrode CPE4 are disposed so as not to overlap the second sub-pixel circuit SPC2, but may be electrically connected to the second sub-pixel circuit SPC2 through the bridge patterns BRE1, BRE2, and BRE3 and the connection pattern BAP.

In one or more embodiments, each of the first bridge pattern BRE1 and the third bridge pattern BRE3 may be disposed to extend from the first sub-display area SDA1 to the second sub-display area SDA2. One first bridge pattern BRE1 may be disposed to overlap at least one of the sub-pixel electrode SAE4, SAE5, and SAE6. On the other hand, the third bridge pattern BRE3 may not necessarily overlap the sub-pixel electrodes SAE4, SAE5, and SAE6. However, the second bridge pattern BRE2 that connects the third bridge pattern BRE3 and the sub-pixel electrodes SAE4, SAE5, and SAE6 may overlap at least the sub-pixel electrodes SAE4, SAE5, and SAE6.

The fourth sub-pixel electrode SAE4 and the fourth copy pixel electrode CPE4 may overlap the opening of the second pixel defining layer 132, and may constitute the light emitting element EL together with the light emitting layer EML disposed at the opening and the common electrode CE disposed on the light emitting layer EML. The electrical signal for light emission of the light emitting element EL may be concurrently (e.g., simultaneously) applied to the fourth sub-pixel electrode SAE4 and the fourth copy pixel electrode CPE4, and the light emitting elements EL including each of them may emit light concurrently (e.g., simultaneously). The light emitting layers EML disposed on the fourth sub-pixel electrode SAE4 and the fourth copy pixel electrode CPE4 may be light emitting layers that emit light of the same color.

The connection patterns BAP may be in contact with the side surfaces and the top surfaces of the sub-pixel electrodes SAE4, SAE5, and SAE6 and the copy pixel electrodes CPE4, CPE5, and CPE6 in the second sub-display area SDA2. In one or more embodiments, the pixel electrode AE, the sub-pixel electrode SAE, and the copy pixel electrode CPE of the display device 10 may have a structure in which one or more electrode layers ET1, ET2, and ET3 are stacked, and the connection pattern BAP may be in contact with the side surfaces or the top surfaces of the electrode layers ET1, ET2, and ET3. For example, each of the pixel electrode AE, the sub-pixel electrode SAE, and the copy pixel electrode CPE may include the first electrode layer ET1, the second electrode layer ET2 disposed on the first electrode layer ET1, and the third electrode layer ET3 disposed on the second electrode layer ET2. The first electrode layer ET1 of each of the sub-pixel electrodes SAE4, SAE5, and SAE6 may be in contact with any one of the bridge patterns BRE1, BRE2, and BRE3. The connection pattern BAP may be in contact with the side surfaces of the first electrode layer ET1, the second electrode layer ET2, and the third electrode layer ET3 of each of the sub-pixel electrode SAE and the copy pixel electrode CPE. Further, the connection pattern BAP may also be in contact with a part of the top surface of the third electrode layer ET3.

The common electrode CE may be disposed over the entire main display area MDA and the entire sub-display area SDA. In the second sub-display area SDA2, the common electrode CE may be disposed on the second pixel defining layer 132 and the plurality of light emitting layers EML. The common electrode CE may also be disposed on the sidewall of the valley portion VA of the second pixel defining layer 132. Because the third interlayer insulating layer ILD3 is exposed at the valley portion VA of the second pixel defining layer 132, the common electrode CE may be in direct contact with the third interlayer insulating layer ILD3. Further, the connection pattern BAP is recessed inward on the bottom surface of the second pixel defining layer 132 at the valley portion VA of the second pixel defining layer 132, so that the common electrode CE may be spaced from the connection pattern BAP.

In the display device 10 according to one or more embodiments, the interlayer insulating layers ILD1, ILD2, and ILD3 and the second pixel defining layer 132 are included in the second sub-display area SDA2, so that the arrangement of the organic insulating material may be reduced or minimized. The first pixel defining layer 131, the sixth insulating layer 128, and the seventh insulating layer 129 containing an organic insulating material may not be disposed in the second sub-display area SDA2. That is, the first pixel defining layer 131, the sixth insulating layer 128, and the seventh insulating layer 129 may not overlap the connection pattern BAP, and the sub-pixel electrode SAE and the copy pixel electrode CPE disposed in the second sub-display area SDA2.

The display device 10 may secure sufficient light transmittance in the second sub-display area SDA2 by reducing or minimizing the arrangement of the organic insulating material. Further, the display device 10 may include the connection patterns BAP that have substantially the same pattern as that of the second pixel defining layer 132 and are spaced from each other with respect to the valley portion VA, so that the sub-pixel electrode and the copy pixel electrode may be connected. In the display device 10, the connection patterns BAP that are distinguished from each other may be formed by a deposition process and an etching process without an additional mask process, so that a fabricating process may be reduced.

Hereinafter, the fabricating process of the structures disposed in the second sub-display area SDA2 of the display device 10 will be described with reference to other drawings.

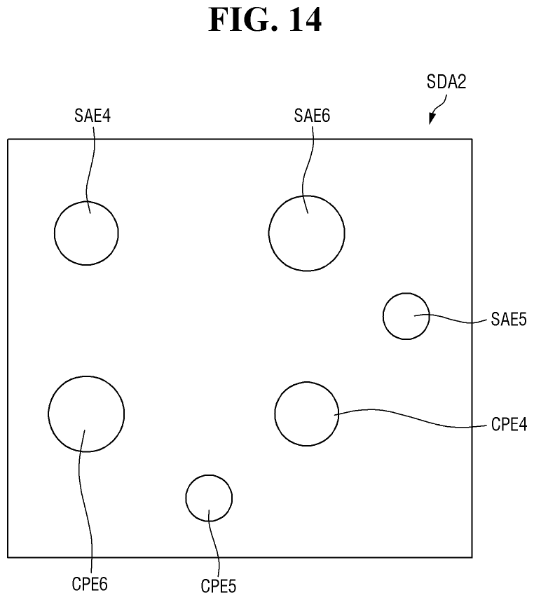

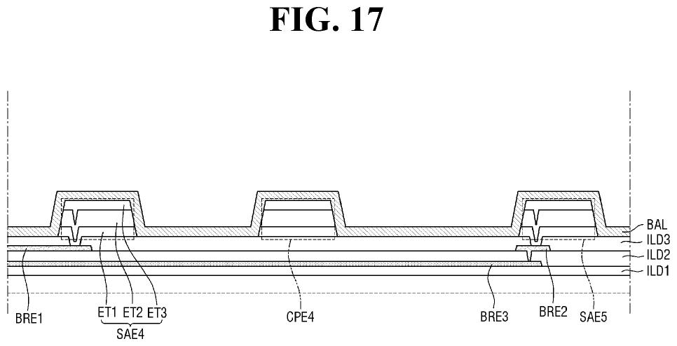

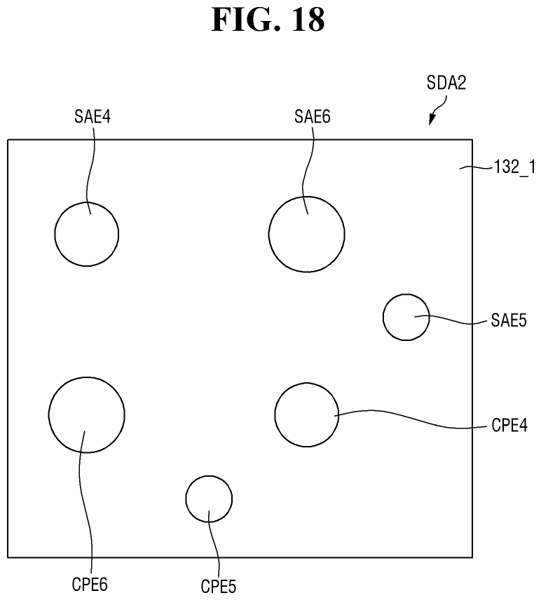

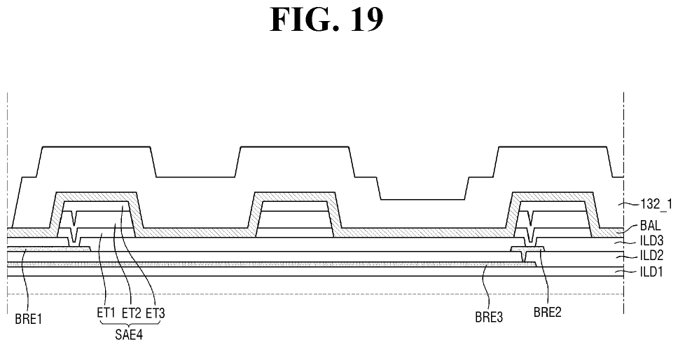

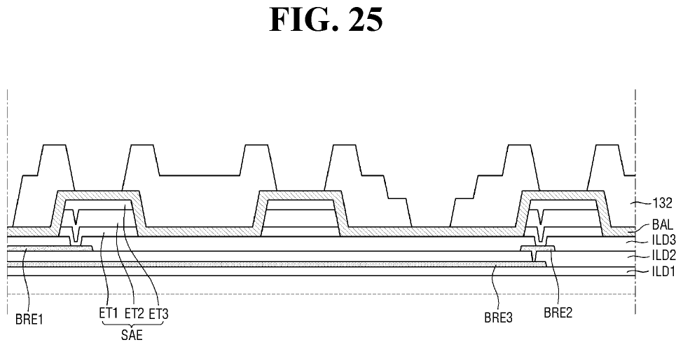

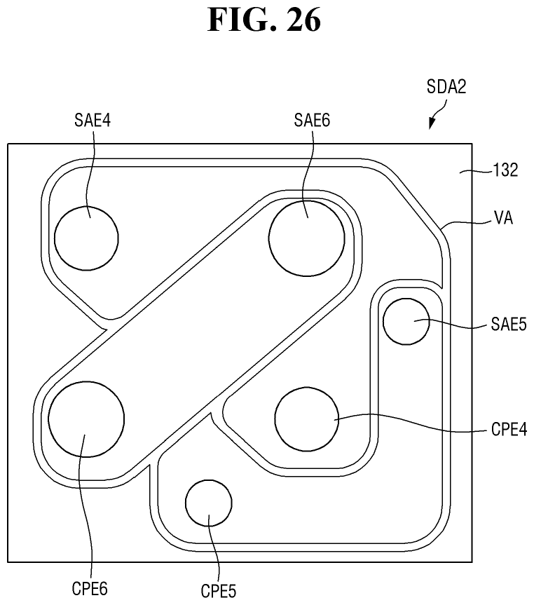

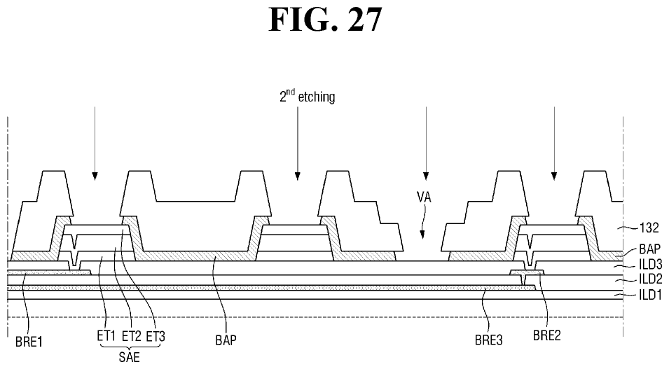

FIGS. 14-28 are diagrams sequentially showing a fabricating process of a display device according to one or more embodiments. FIGS. 14-28 sequentially illustrate the process of forming a plurality of sub-pixel electrodes and copy pixel electrodes, the connection pattern BAP, and the second pixel defining layer 132 in the second sub-display area SDA2 of the display device 10.

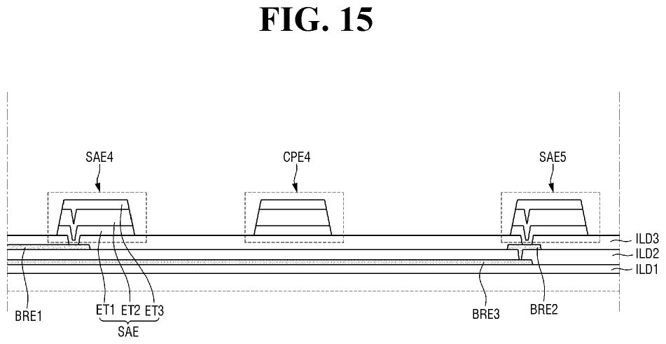

Referring to FIGS. 14 and 15, the plurality of sub-pixel electrodes SAE4, SAE5, and SAE6 and the plurality of copy pixel electrodes CPE4, CPE5, and CPE6 are formed on the third interlayer insulating layer ILD3 in the second sub-display area SDA2 of the display device 10. In one or more embodiments, the layers disposed under the third interlayer insulating layer ILD3 may be formed by typical deposition, etching, and mask processes, and the structures thereof are the same as described above, so that the detailed description thereof will be omitted. FIG. 14 illustrates the plurality of sub-pixel electrodes SAE4, SAE5, and SAE6 and the plurality of copy pixel electrodes CPE4, CPE5, and CPE6 disposed in the second sub-display pixel SDX2 of the second sub-display area SDA2, and FIG. 15 illustrates the fourth sub-pixel electrode SAE4, the fifth sub-pixel electrode SAE5, and the fourth copy pixel electrode CPE4.

The fourth sub-pixel electrode SAE4 may be connected to the first bridge pattern BRE1, and the fifth sub-pixel electrode SAE5 may be connected to the second bridge pattern BRE2 and the third bridge pattern BRE3. On the other hand, the fourth copy pixel electrode CPE4 may not be connected to the bridge patterns BRE1, BRE2, and BRE3. However, the sub-pixel electrodes SAE4, SAE5, and SAE6 and the bridge patterns BRE1, BRE2, and BRE3 illustrated in FIG. 15 are merely one example, and the display device 10 is not necessarily limited to this structure.

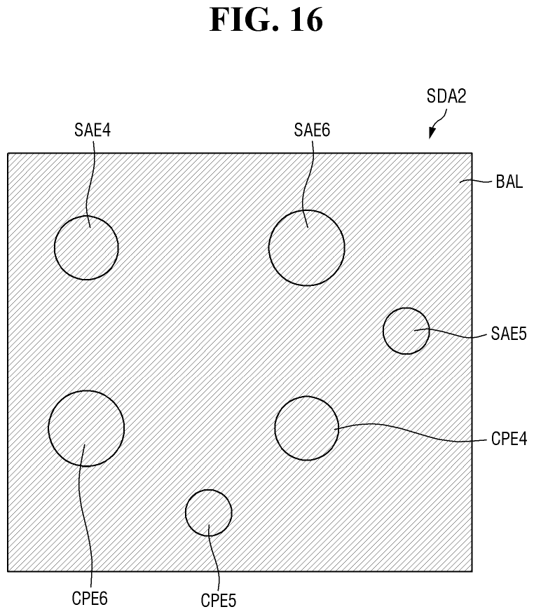

Next, referring to FIGS. 16-19, a connection pattern layer BAL and an inorganic insulating layer 132_1 are sequentially formed on the third interlayer insulating layer ILD3, the plurality of sub-pixel electrodes SAE and the plurality of copy pixel electrodes CPE. The connection pattern layer BAL may be disposed to cover all the sub-pixel electrodes SAE and the copy pixel electrodes CPE disposed on the third interlayer insulating layer ILD3, and the inorganic insulating layer 132_1 may be disposed on the connection pattern layer BAL. The connection pattern layer BAL may be patterned in a subsequent process to form the connection pattern BAP, and the inorganic insulating layer 132_1 may form the second pixel defining layer 132.

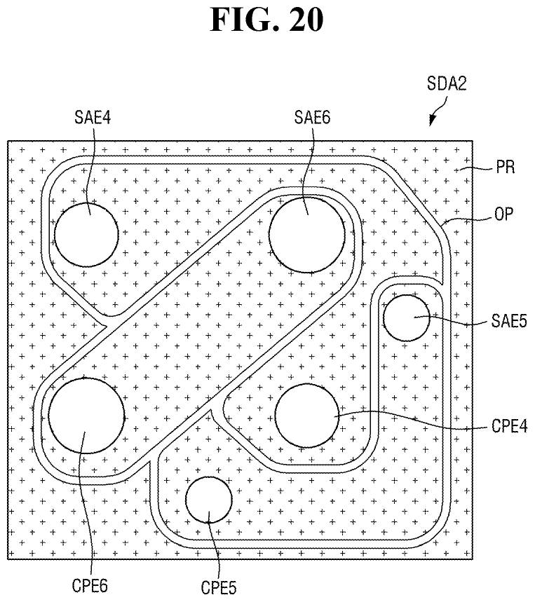

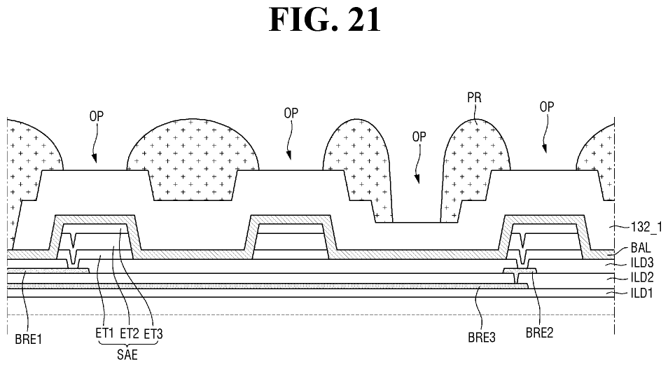

Next, referring to FIGS. 20 and 21, a photoresist PR including a plurality of openings OP is formed on the inorganic insulating layer 132_1. The photoresist PR may include the plurality of openings OP that overlap the sub-pixel electrodes SAE and the copy pixel electrodes CPE. Some of the openings OP may be formed in the area that does not overlap the sub-pixel electrodes SAE and the copy pixel electrodes CPE. However, the opening OP that does not overlap the sub-pixel electrodes SAE and the copy pixel electrodes CPE may have a closed loop shape in a plan view and may be around (e.g., may surround) a pair of one of the sub-pixel electrodes SAE and one of the copy pixel electrodes CPE.

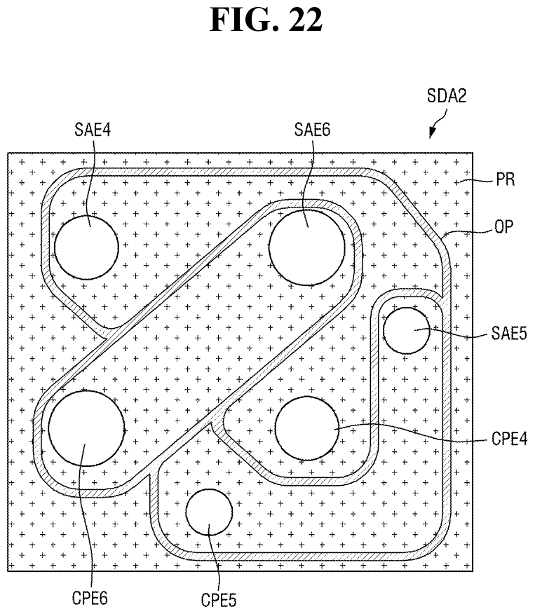

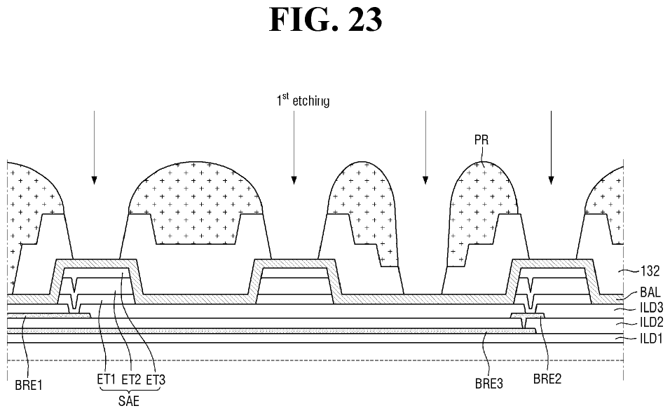

Next, referring to FIGS. 22 and 23, a first etching process (1^{st} etching) for forming the second pixel defining layer 132 by patterning the inorganic insulating layer 132_1 along the opening OP of the photoresist PR is performed. In this process, in the inorganic insulating layer 132_1, the area where the opening OP of the photoresist PR is located may be etched, and the portion that overlaps the sub-pixel electrodes SAE and the copy pixel electrodes CPE may be removed. Further, in the inorganic insulating layer 132_1, the portion of the opening OP that is around (e.g., that surrounds) a pair of one of the sub-pixel electrodes SAE and one of the copy pixel electrodes CPE in a closed loop shape may also be removed. The connection pattern layer BAL may be exposed at the portion where the inorganic insulating layer 132_1 is etched and removed. The second pixel defining layer 132 may be formed in this process. In one or more embodiments, the first etching process (1^{st} etching) may be a dry etching process.

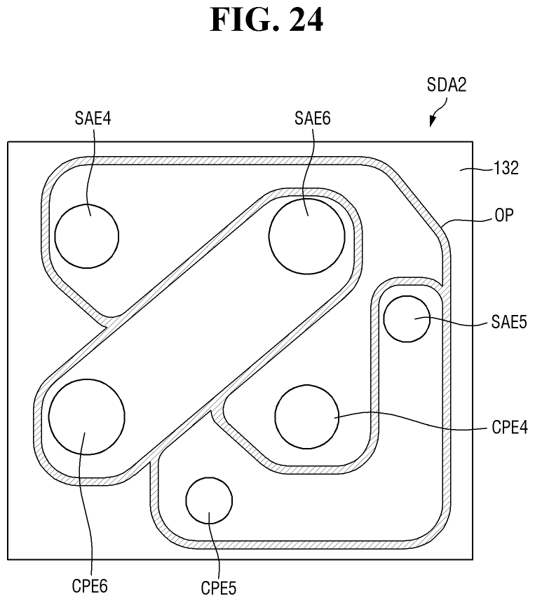

Next, referring to FIGS. 24-27, after the photoresist PR is removed, a second etching process (2^{nd} etching) for etching the connection pattern layer BAL along the opening OP of the second pixel defining layer 132 is performed. For example, the photoresist PR may be removed by a strip process, but the present disclosure is not limited thereto. In this process, the connection pattern layer BAL may be partially etched to form the connection pattern BAP. The connection patterns BAP remaining in the second etching process (2^{nd} etching) may serve as the bridge electrode of a pair of one of the sub-pixel electrodes SAE4, SAE5, and SAE6 and one of the copy pixel electrodes CPE4, CPE5, and CPE6 in the second sub-display area SDA2.

In one or more embodiments, the connection pattern layer BAL may contain a material different from that of the inorganic insulating layer 132_1. As described above, the connection pattern BAP and the connection pattern layer BAL may include at least one of IZO, IGZO, ITGZO, ITO, ITZO, ITGO, and/or IGO, and may prevent the sub-pixel electrodes SAE4, SAE5, and SAE6 and the copy pixel electrodes CPE4, CPE5, and CPE6 disposed thereunder from being damaged in the first etching process (1^{st} etching) that is the etching process of the inorganic insulating layer 132_1.

The area of the connection pattern layer BAL that is exposed by the opening of the second pixel defining layer 132 may be removed, and the top surfaces of the sub-pixel electrodes SAE and the copy pixel electrodes CPE may be partially exposed at the portion where the connection pattern layer BAL is etched and removed. Here, the portion of the connection pattern layer BAL that is covered by the second pixel defining layer 132 may be further etched. Accordingly, the connection pattern BAP may be recessed and located on the bottom surface of the second pixel defining layer 132 at the portion of the opening of the second pixel defining layer 132 where the sub-pixel electrodes SAE and the copy pixel electrodes CPE are exposed.

Further, in the area of the opening of the second pixel defining layer 132 that has a closed loop shape and is around (e.g., surrounds) a pair of the sub-pixel electrodes SAE and the copy pixel electrodes CPE, the connection pattern layer BAL may be partially removed to form the valley portion VA. The plurality of connection patterns BAP may be spaced from each other and distinguished with respect to the valley portion VA. In one or more embodiments, the second etching process (2^{nd} etching) may be a wet etching process.

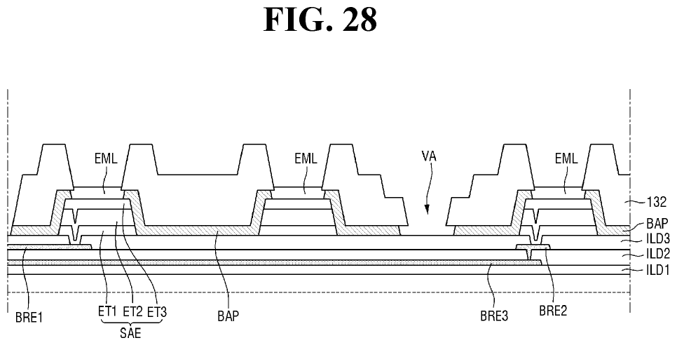

Next, referring to FIG. 28, the light emitting layer EML may be formed on the sub-pixel electrodes SAE and the copy pixel electrodes CPE exposed by the opening of the second pixel defining layer 132, and the common electrode CE, the encapsulation layer 140, and the like may be formed on the light emitting layer EML, thereby fabricating the display device 10.

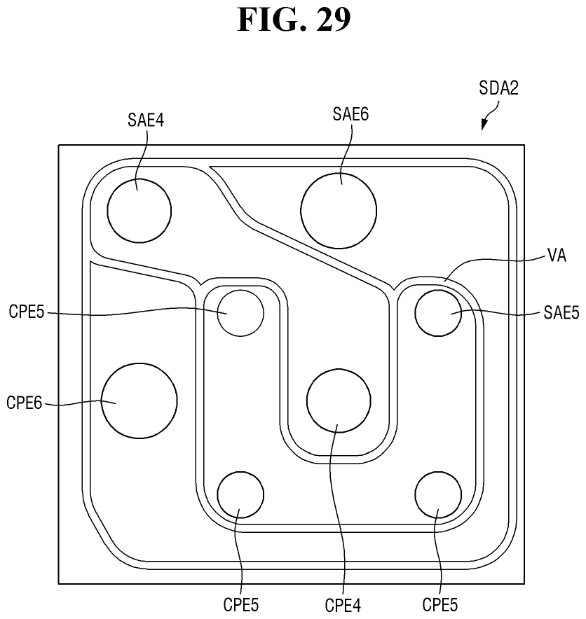

FIG. 29 is a diagram showing one pixel of a second sub-display area of a display device according to one or more embodiments.

Referring to FIG. 29, in the display device 10 according to one or more embodiments, one fifth sub-pixel electrode SAE5 may be electrically connected to three fifth copy pixel electrodes CPE5 in the second sub-display area SDA2. The embodiment is different from the embodiment of FIG. 8 in that some sub-pixel electrodes (e.g., the fifth sub-pixel electrode) may be driven concurrently (e.g., simultaneously) in groups with one or more copy pixel electrodes CPE.

The display device 10 may adjust the configuration of the light emitting elements that emit light of a specific color by adjusting the number of the pixel electrodes AE constituting one pixel PX. Similarly, the number of the copy pixel electrodes CPE connected to one sub-pixel electrode SAE in the second sub-display area SDA2 may be adjusted to adjust the number of the light emitting elements that emit light of a specific color in the corresponding sub-display pixel (e.g., the second sub-display pixel SDX2).

Because a larger number of copy pixel electrodes CPE are disposed in the second sub-display area SDA2, the planar shape of the valley portion VA or the connection pattern BAP may be changed. However, as described above, the shape of the valley portion VA may be variously changed according to the number and arrangement of the sub-pixel electrode SAE and the copy pixel electrode CPE forming one group, and the shape of the connection pattern BAP may also be changed according to the closed loop shape of the valley portion VA. The display device 10 may have partially low resolution because the pixel structure of the sub-display areas SDA1 and SDA2 is different from that of the main display area MDA, but the resolution difference may be compensated by adjusting the number of the sub-pixel electrode SAE and the copy pixel electrode CPE forming one group.

In concluding the detailed description, those skilled in the art will appreciate that many variations and modifications can be made to the embodiments without substantially departing from the spirit, scope, and principles of the present disclosure. Therefore, the embodiments of the present disclosure are used in a generic and descriptive sense only and not for purposes of limitation.

What is claimed is:

1. A display device comprising:
a main display area, and a first sub-display area and a second sub-display area surrounded by the main display area and located adjacent to each other;
a plurality of pixel electrodes in the main display area and spaced from each other;
a plurality of first sub-pixel electrodes in the first sub-display area and spaced from each other;
a plurality of first copy pixel electrodes in the first sub-display area and connected to the first sub-pixel electrodes via a first bridge electrode;
a first pixel defining layer in the main display area and the first sub-display area, and having a plurality of openings therein that overlaps the plurality of pixel electrodes, the plurality of first sub-pixel electrodes, and the plurality of first copy pixel electrodes, respectively;
a plurality of second sub-pixel electrodes and second copy pixel electrodes in the second sub-display area and spaced from each other;
a plurality of connection patterns in the second sub-display area, and each connected to one of the plurality of second sub-pixel electrodes and one of the second copy pixel electrodes; and
a second pixel defining layer on the connection patterns, and having a plurality of openings therein that overlaps the plurality of second sub-pixel electrodes and second copy pixel electrodes, respectively,
wherein the second pixel defining layer comprises a valley portion around a second sub-pixel electrode of the plurality of second sub-pixel electrodes and a second copy pixel electrode of the second copy pixel electrodes connected to each other through a connection pattern from among the plurality of connection patterns.

2. The display device of claim 1, wherein the connection pattern is recessed inward from sidewalls of the valley portion and an opening from among the openings of the second pixel defining layer.

3. The display device of claim 1, wherein the plurality of connection patterns are separated from each other with respect to the valley portion of the second pixel defining layer.

4. The display device of claim 1, wherein the connection pattern is in contact with a side surface of each of the second sub-pixel electrode and the second copy pixel electrode.

5. The display device of claim 4, wherein the connection pattern is in contact with a part of a top surface of each of the second sub-pixel electrode and the second copy pixel electrode.

6. The display device of claim 1, further comprising a common electrode on the main display area, the first sub-display area, and the second sub-display area,
wherein the common electrode is in the valley portion of the second pixel defining layer in the second sub-display area.

7. The display device of claim 6, wherein the common electrode is not in contact with the connection pattern.

8. The display device of claim 1, wherein the first pixel defining layer comprises an organic insulating material, and the second pixel defining layer comprises an inorganic insulating material.

9. The display device of claim 1, further comprising a first bridge pattern extending from the first sub-display area to the second sub-display area, and connected to one of the plurality of second sub-pixel electrodes.

10. The display device of claim 9, further comprising:
a second bridge pattern overlapping another one of the plurality of second sub-pixel electrodes; and
a third bridge pattern connected to the second bridge pattern and extending from the first sub-display area to the second sub-display area.

11. The display device of claim 10, further comprising a plurality of interlayer insulating layers in the second sub-display area,
wherein the first bridge pattern and the second bridge pattern are on an interlayer insulating layer from among the plurality of interlayer insulating layers that is different from another interlayer insulating layer from among the plurality of interlayer insulating layers on which the third bridge pattern is located.

12. The display device of claim 9, further comprising a plurality of first sub-pixel circuits and a plurality of second sub-pixel circuits in the first sub-display area,
wherein the first sub-pixel electrodes overlap at least one of the plurality of the first sub-pixel circuits, at least some of the first copy pixel electrodes overlap at least one of the plurality of the second sub-pixel circuits, and the first bridge pattern is electrically connected to one of the plurality of second sub-pixel circuits.

13. The display device of claim 1, further comprising:
a first interlayer insulating layer in the main display area, the first sub-display area, and the second sub-display area; and
a first insulating layer on the first interlayer insulating layer and in the main display area and the first sub-display area,
wherein the first insulating layer comprises an organic insulating material, and the first interlayer insulating layer comprises an inorganic insulating material.

14. The display device of claim 13, wherein the first insulating layer does not overlap the connection pattern, the second sub-pixel electrode, and the second copy pixel electrode.

15. The display device of claim 1, wherein the first sub-pixel electrodes, the first copy pixel electrodes, and the first bridge electrode in the first sub-display area are integrated.

16. A method for fabricating a display device, comprising:
preparing a substrate having a plurality of bridge patterns and an interlayer insulating layer on the bridge patterns, and forming a plurality of sub-pixel electrodes and copy pixel electrodes spaced from each other on the interlayer insulating layer;
forming a connection pattern layer on the interlayer insulating layer and covering the sub-pixel electrodes and the copy pixel electrodes, and forming an inorganic insulating layer on the connection pattern layer;
forming a photoresist comprising a plurality of openings surrounding a pair of the sub-pixel electrode and the copy pixel electrode without overlapping the sub-pixel electrodes and the copy pixel electrodes, or overlapping one of the sub-pixel electrodes and the copy pixel electrodes, and on the inorganic insulating layer;
forming a pixel defining layer by etching the inorganic insulating layer along the opening of the photoresist, and etching the connection pattern layer along an opening formed in the pixel defining layer to partially expose top surfaces of the sub-pixel electrode and the copy pixel electrode; and
forming a light emitting layer on each of the sub-pixel electrode and the copy pixel electrode, and forming a common electrode on the light emitting layer and the pixel defining layer.

17. The method of claim 16, wherein the pixel defining layer comprises a valley portion formed by etching along an opening from among the openings around the pair of the sub-pixel electrode and the copy pixel electrode, and in the forming of the connection pattern layer, the connection pattern layer is etched along the valley portion to form a plurality of connection patterns separated from each other with respect to the valley portion.

18. The method of claim 17, wherein the connection pattern is in contact with each of the pair of the sub-pixel electrode and the copy pixel electrode.

19. The method of claim 17, wherein in the forming of the connection pattern layer, the connection pattern layer is etched along the opening of the pixel defining layer, and the connection pattern partially exposes top surfaces of the sub-pixel electrode and the copy pixel electrode.

20. The method of claim 17, wherein the connection pattern is recessed inward from sidewalls of the valley portion and the opening of the pixel defining layer.
